(19) United States
(12) Patent Application Publication
(10) Pub. No.: US 2007/0045757 A1
(43) Pub. Date: Mar. 1, 2007

(54) Sensor

(75) Inventors: Naoteru Matsubara, Anpachi-gun (JP); Yohko Naruse, Ichinomiya-shi (JP)

Correspondence Address: MCDERMOTT WILL & EMERY LLP, 600 13TH STREET, N.W., WASHINGTON, DC, 20005-3096, US

(73) Assignee: SANYO ELECTRIC CO., LTD.

(21) Appl. No.: 11/512,322

(22) Filed: Aug. 30, 2006

(30) Foreign Application Priority Data
Aug. 31, 2005 (JP) JP2005-252114
Sep. 22, 2005 (JP) JP2005-276303

(51) Int. Cl. H01L 29/84; G01R 27/26

(52) U.S. Cl. 257/416; 324/661

(57) ABSTRACT

A sensor capable of increasing an electric signal output therefrom by inhibiting an electrode plate from vibration is obtained. This sensor comprises a diaphragm provided in a vibrative manner, an electrode plate, opposed to the diaphragm at a prescribed distance, having a hole and a support made of a material having an elastic modulus higher than the elastic modulus of a material constituting the electrode plate for supporting the electrode plate. The support is so formed as to cover at least two of the upper surface and the lower surface of the electrode plate and the side surface of the hole.

### BACKGROUND OF THE INVENTION

1. Field of the Invention

The present invention relates to a sensor, and more particularly, it relates to a sensor having a support supporting an electrode plate.

2. Description of the Background Art

A sensor such as a sonic sensor converting a sound to an electric signal by change in the electrostatic capacitance between a sonically vibrating diaphragm and an electrode plate is known in general, as disclosed in National Patent Publication Gazette No. 2004-506394, for example.

The aforementioned National Patent Publication Gazette No. 2004-506394 discloses a sonic sensor comprising a vibrative diaphragm, an electrode plate and a support supporting the electrode plate. When this sonic sensor receives a sound, the diaphragm so vibrates as to change the electrostatic capacitance between the diaphragm and the electrode plate, subjected to application of a constant voltage. Charges move from the diaphragm and the electrode plate due to this change in the electrostatic capacitance, so that the sonic sensor outputs the change of the charges as an electric signal with respect to the sound. In this sonic sensor according to National Patent Publication Gazette No. 2004-506394, the support supports only the upper surface of the electrode plate.

In the sonic sensor according to the aforementioned National Patent Publication Gazette No. 2004-506394, however, the support supports only the upper surface of the electrode plate, leading to such a disadvantage that the electrode plate easily vibrates. When the electrode plate vibrates in the same direction as the diaphragm, therefore, change in the distance between the electrode plate and the diaphragm is reduced to reduce the change in the electrostatic capacitance between the electrode plate and the diaphragm. In this case, the quantity of charges moving from the electrode and the diaphragm is reduced to disadvantageously reduce the electric signal output from the sonic sensor.

### SUMMARY OF THE INVENTION

The present invention has been proposed in order to solve the aforementioned problem, and an object of the present invention is to provide a sensor capable of increasing an electric signal output therefrom by inhibiting an electrode plate from vibration.

A sensor according to a first aspect of the present invention comprises a diaphragm provided in a vibrative manner, an electrode plate, opposed to the diaphragm at a prescribed distance, having a hole and a support made of a material having an elastic modulus higher than the elastic modulus of a material constituting the electrode plate for supporting the electrode plate, and the support is so formed as to cover at least two of the upper surface and the lower surface of the electrode plate and the side surface of the hole. The lower surface of the electrode plate is closer to the diaphragm, while the upper surface of the electrode plate is farther from the diaphragm.

In the sensor according to the first aspect of the present invention, the support having the higher elastic modulus is so formed as to cover at least two of the upper surface and the lower surface of the electrode plate and the side surface of the hole so that bearing strength of the support for the electrode plate can be further improved as compared with a case of forming the support to cover only the upper or lower surface of the electrode plate, thereby inhibiting the electrode plate from vibration. Thus, only the diaphragm can remarkably vibrate when the sensor receives a sound or the like, so that change in the electrostatic capacitance between the diaphragm and the electrode plate can be increased. Consequently, the change in the electrostatic capacitance between the diaphragm and the electrode plate can be so increased as to increase an electric signal output from the sensor. When the support having the higher elastic modulus supports both of the upper and lower surfaces of the electrode plate maximumly expanded or contracted to receive maximum tensile stress and maximum compressive stress upon vibration of the electrode plate and the support, bearing strength of the support for the electrode plate can be improved also when the total thickness of parts of the support formed on the upper and lower surfaces of the electrode plate respectively is identical to the thickness of a support formed only on the upper or lower surface of the electrode plate. Thus, the bearing strength for the electrode plate can be improved without increasing the thickness of the support dissimilarly to a case of supporting only the upper or lower surface of the electrode plate with the support, thereby preventing the support from cracking resulting from an increased thickness thereof.

In the aforementioned sensor according to the first aspect, the support is preferably so formed as to cover the upper surface and the lower surface of the electrode plate. Thus, the support having the higher elastic modulus supports both of the upper and lower surfaces maximumly expanded or contracted to receive maximum tensile stress and maximum compressive stress upon vibration of the electrode plate and the support, thereby effectively inhibiting the electrode plate from vibration.

In the aforementioned sensor having the support covering the upper and lower surfaces of the electrode plate, the ratio of the longitudinal sectional area of the support to the total longitudinal sectional area of the electrode plate and the support in portions of the support covering the upper surface and the lower surface of the electrode plate is preferably at least 10%. According to this structure, the electrode plate can be further inhibited from vibration.

In the aforementioned sensor according to the first aspect, the support is preferably so formed as to cover either the upper surface or the lower surface of the electrode plate and the side surface of the hole. Thus, the support having the higher elastic modulus supports the upper surface (lower surface) of the electrode plate receiving maximum tensile stress or maximum compressive stress while the lower end (upper end) of the support provided on the side surface of the hole partially supports the lower surface (upper surface) of the electrode plate receiving the maximum tensile stress or the maximum compressive stress upon vibration of the electrode plate and the support, thereby inhibiting the electrode plate from vibration.

In this case, the ratio of the longitudinal sectional area of the support to the total longitudinal sectional area of the electrode plate and the support in portions of the support covering either the upper surface or the lower surface of the electrode plate and the side surface of the hole is preferably at least 26%. According to this structure, the electrode plate can be further inhibited from vibration.

In the aforementioned sensor according to the first aspect, the support is preferably so formed as to cover the upper surface and the lower surface of the electrode plate and the side surface of the support. Thus, the support having the higher elastic modulus supports the upper and lower surfaces of the electrode plate receiving the maximum tensile stress and the maximum compressive stress upon vibration of the electrode plate and the support, thereby inhibiting the electrode plate from vibration.

In this case, the ratio of the longitudinal sectional area of the support to the total longitudinal sectional area of the electrode plate and the support in portions of the support covering the upper surface and the lower surface of the electrode plate and the side surface of the support is preferably at least 17%. According to this structure, the electrode plate can be further inhibited from vibration.

In the aforementioned sensor according to the first aspect, the electrode plate preferably consists of silicon, and the support preferably consists of SiN. According to this structure, the support can easily attain the elastic modulus higher than that of the electrode plate.

In the aforementioned sensor according to the first aspect, the support preferably includes an upper support layer covering the upper surface of the electrode plate, and the upper support layer preferably includes a first opening provided in a contact region of the electrode plate for exposing a prescribed portion of the upper surface of the electrode plate. According to this structure, the electrode plate and an external wire can be electrically connected with each other through the first opening despite the upper support layer provided on the electrode plate.

In this case, the sensor preferably further comprises a first pad electrode so formed as to come into contact with the electrode plate through the first opening of the upper support layer. According to this structure, the electrode plate and the external wire can be electrically connected with each other through the first pad electrode provided in the first opening.

In the aforementioned sensor according to the first aspect, the support preferably includes an upper support layer covering the upper surface of the electrode plate and a lower support layer covering the lower surface of the electrode plate or the lower surface of the upper support layer, and the upper support layer and the lower support layer preferably include second openings provided in a contact region of the diaphragm for exposing a prescribed portion of the upper surface of the diaphragm. According to this structure, the diaphragm and the external wire can be electrically connected with each other through the second openings despite the upper and lower support layers provided on the diaphragm.

In this case, the sensor preferably further comprises a second pad electrode so formed as to come into contact with the diaphragm through the second openings of the upper support layer and the lower support layer. According to this structure, the diaphragm and the external wire can be electrically connected with each other through the second pad electrode provided in the second openings.

In the aforementioned sensor according to the first aspect, the support is preferably formed by an insulating film. According to this structure, the diaphragm and the electrode plate can be easily electrically insulated from each other through the support formed by the insulating film.

In the aforementioned sensor having the support formed by the insulating film, the support is preferably formed by the insulating film containing an impurity introduced by ion implantation. According to modification employing ion implantation, the temperature of the insulating film is substantially increased to about 800° C. during implantation of the impurity, so that the insulating film is densified. At this time, the insulating film is densified while bonds therein are cut due to the implanted impurity, so that the insulating film is relieved from stress. After implantation of the impurity, the insulating film develops expansive force when returning from the temperature of about 800° C. to an equilibrium state of the room temperature, to result in compressive stress (stress acting in an expansive direction with respect to an underlayer) applied to the insulating film. Thus, compressive stress (stress acting in an expansive direction with respect to the underlayer) is applied to the insulating film due to ion implantation, to fix the electrode plate in an outwardly pulled state (in the expansive direction with respect to the underlayer). When a pressure is applied to the electrode plate, therefore, the electrode plate is inhibited from vibration (displacement). Consequently, noise added to a pressure signal is reduced as compared with a case of employing an insulating film subjected to no ion implantation, whereby the sensor has low noise to be capable of correctly measuring capacitance change.

In the aforementioned sensor having the support formed by the insulating film, the support formed by the insulating film containing the impurity introduced by ion implantation preferably contains Si, O and C. According to this structure, the impurity is introduced into the insulating film containing Si, O and C, whereby the dielectric constant of the insulating film can be reduced as compared with that of a conventional insulating film such as a silicon oxide film or a silicon nitride film. Thus, a parasitic capacitance (≈dielectric constant of material×area/thickness) resulting from the insulating film fixing the electrode plate can be so reduced as to improve sensitivity (≈bias voltage×electrostatic capacitance change resulting from vibration/electrostatic capacitance) of the sensor. Further, the impurity is so introduced into the insulating film containing Si, O and C as to densify the insulating film by ion implantation and to subsequently further expand the insulating film, thereby causing compressive stress (stress acting in the expansive direction with respect to the underlayer) higher than that in the conventional insulating film. Therefore, the insulating film fixes the electrode plate in the outwardly pulled state (in the expansive direction with respect to the underlayer), thereby further inhibiting the electrode plate from vibration (displacement) when a pressure is applied to the electrode plate. Consequently, noise added to the pressure signal is further reduced as compared with a case of employing the conventional insulating film, whereby the sensor has lower noise to be capable of more correctly measuring capacitance change.

In the aforementioned sensor having the support formed by the insulating film, the insulating film preferably includes a first region containing the impurity and a second region containing no impurity. According to this structure, the insulating film fixing the electrode plate so includes the first region containing the impurity as to fix the electrode plate in the outwardly pulled state, thereby inhibiting the electrode plate from vibration (displacement) resulting from propagation of a sound wave or the like. The insulating film containing the impurity is densified by ion implantation, to exhibit a dielectric constant higher than that before ion implantation. Therefore, the insulating film so includes the second region containing no impurity that the dielectric constant thereof can be reduced as compared with an insulating film constituted of only the first region. Consequently, the parasitic capacitance, resulting from the insulating film fixing the electrode plate, added to the electrostatic capacitance between the diaphragm and the electrode plate can be so reduced as to improve the sensitivity of the sensor.

In the aforementioned sensor having the support formed by the insulating film, the impurity is preferably introduced into the electrode plate through the insulating film. According to this structure, adhesiveness between the electrode plate and the insulating film is improved due to mixing action on the interface between the electrode plate and the insulating film, thereby more strongly fixing the electrode plate in the state pulled by the insulating film. Thus, noise resistance with respect to the pressure signal can be further improved.

In the aforementioned sensor having the support formed by the insulating film containing the impurity introduced by ion implantation, the support formed by the insulating film preferably has stress outwardly pulling the electrode plate. According to this structure, the insulating film fixes the electrode plate in the outwardly pulled state (in the expansive direction with respect to the underlayer), thereby inhibiting the electrode plate from vibration (displacement) when a pressure is applied to the electrode plate. Consequently, noise added to the pressure signal is further reduced as compared with the case of employing the conventional insulating film, whereby the sensor has low noise to be capable of correctly measuring capacitance change.

The aforementioned sensor according to the first aspect may include a sonic sensor.

A sensor according to a second aspect of the present invention comprises a first electrode provided on a semiconductor substrate, a second electrode opposed to the first electrode at a prescribed interval for constituting a capacitor with the first electrode and an insulating film provided on at least the upper surface of the second electrode for fixing the second electrode to the semiconductor substrate. An impurity is introduced into the insulating film by ion implantation. According to modification employing ion implantation, the temperature of the insulating film is substantially increased to about 800° C. during implantation of the impurity, so that the insulating film is densified. At this time, the insulating film is densified while bonds therein are cut due to the implanted impurity, so that the insulating film is relieved from stress. After implantation of the impurity, the insulating film develops expansive force when returning from the temperature of about 800° C. to an equilibrium state of the room temperature, to result in compressive stress (stress acting in an expansive direction with respect to an underlayer) applied to the insulating film. Thus, compressive stress (stress acting in the expansive direction with respect to the underlayer) is applied to the insulating film due to ion implantation, to fix the electrode plate in an outwardly pulled state (in the expansive direction with respect to the underlayer). When a pressure is applied to the second electrode, therefore, the second electrode is inhibited from vibration (displacement). Consequently, noise added to a pressure signal is reduced as compared with a case of employing an insulating film subjected to no ion implantation, whereby the sensor has low noise to be capable of correctly measuring capacitance change.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a sectional view taken along a line 100-100 in FIG. 3 for illustrating the structure of a microphone according to a first embodiment of the present invention;

FIG. 2 is a sectional view taken along a line 150-150 in FIG. 3 for illustrating the structure of the microphone according to the first embodiment of the present invention;

FIGS. 3 and 4 are plan views of the microphone according to the first embodiment of the present invention shown in FIG. 1;

FIG. 5 is a sectional view for illustrating operations of the microphone according to the first embodiment shown in FIG. 1;

FIG. 6 is a schematic diagram showing each of models of flat plates having supported single ends employed for simulations;

FIGS. 7 to 13 are sectional views taken along the line 200-200 in FIG. 6 for illustrating the models of the flat plates employed for the simulations respectively;

FIG. 14 is a graph showing the relation between the ratios (%) of the longitudinal sectional areas of supports to the total longitudinal sectional areas (6 μm²) of electrode plates and the supports and displacements y (nm);

FIG. 15 is a graph showing the relation between the thicknesses (μm) of the supports and the displacements y (nm);

FIGS. 16 to 30 are sectional views for illustrating a process of manufacturing the microphone according to the first embodiment of the present invention;

FIG. 31 is a sectional view showing the structure of a microphone according to a second embodiment of the present invention;

FIGS. 32 to 36 are sectional views for illustrating a process of manufacturing the microphone according to the second embodiment of the present invention;

FIG. 37 is a top plan view showing the structure of a sonic sensor according to a third embodiment of the present invention;

FIG. 38 is a sectional view taken along the line 400-400 in FIG. 37;

FIG. 39 is a sectional view taken along the line 450-450 in FIG. 37;

FIGS. 40 to 51 are sectional views for illustrating a process of manufacturing the sonic sensor according to the third embodiment of the present invention;

FIG. 52 is a sectional view showing a sonic sensor according to a fourth embodiment of the present invention;

FIG. 53 is a sectional view showing the structure of a microphone according to a first modification of the present invention; and

FIG. 54 is a sectional view showing the structure of a microphone according to a second modification of the present invention.

### DESCRIPTION OF THE PREFERRED EMBODIMENTS

Embodiments of the present invention are now described. In the following description, each embodiment of the present invention is applied to a microphone (sonic sensor) employed as an exemplary sensor.

### First Embodiment

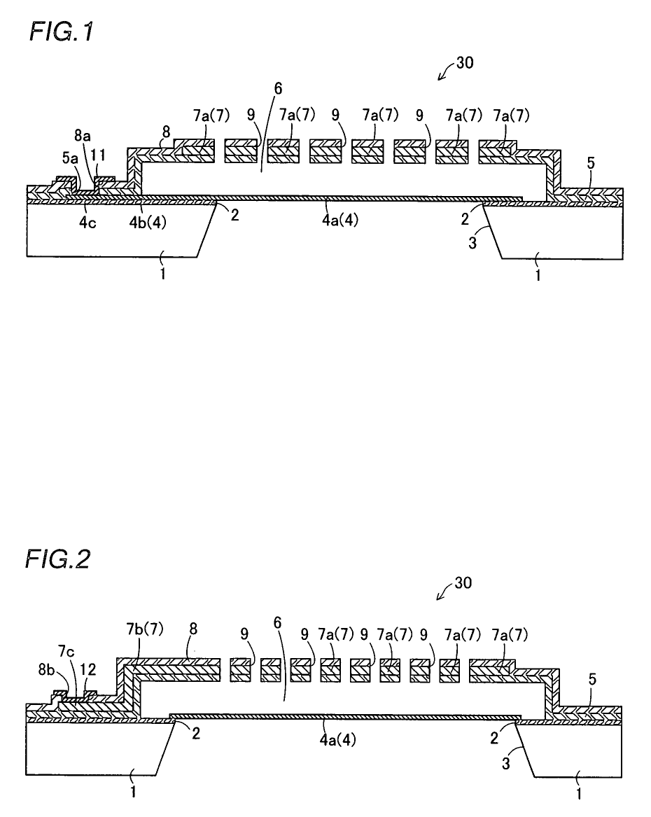

The structure of a microphone 30 according to a first embodiment of the present invention is described with reference to FIGS. 1 to 4.

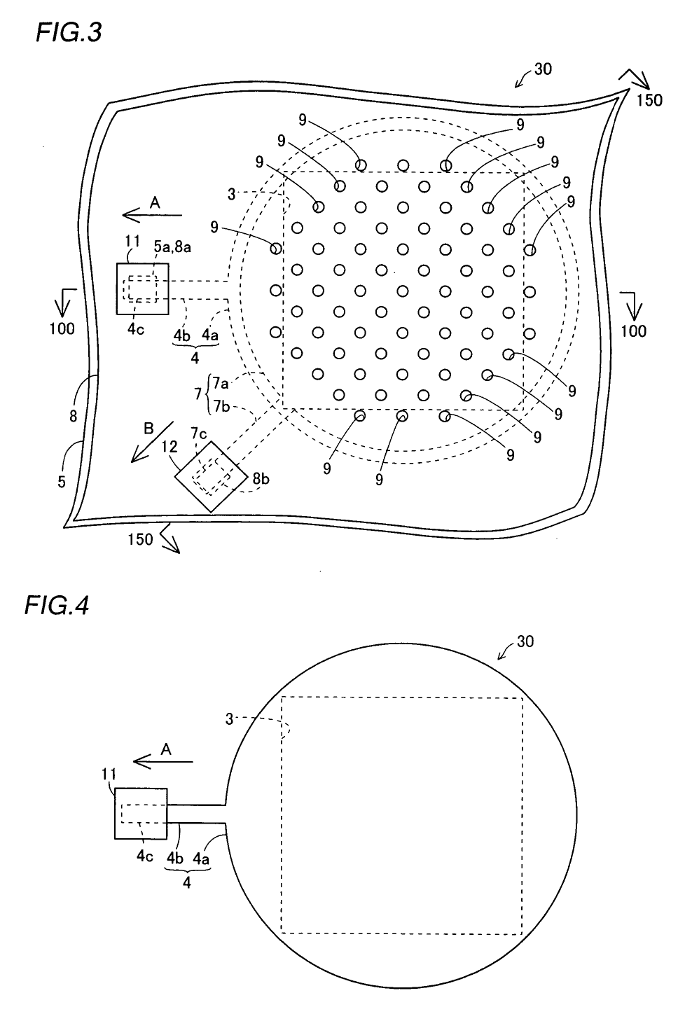

In the microphone 30 according to the first embodiment, an etching stopper layer 2 of SiN is formed on the surface of a silicon substrate 1, as shown in FIGS. 1 and 2. This etching stopper layer 2 has a thickness of about 0.05 μm to about 0.2 μm. A partially square-pyramidal (truncated square-pyramidal) opening 3 (see FIGS. 1 and 3) is formed in a region formed with a diaphragm 4a described later, to pass through the silicon substrate 1 and the etching stopper layer 2. This opening 3 functions as an air passage when the microphone 30 receives a sound.

A polysilicon layer 4 having a thickness of about 0.1 μm to about 2.0 μm is formed on the upper surfaces of the etching stopper layer 2 and the opening 3. This polysilicon layer 4 is doped with an n-type impurity (phosphorus (P)), to be conductive. As shown in FIGS. 3 and 4, the polysilicon layer 4 includes a discoidal diaphragm portion 4a concentric with the opening 3 in plan view and a connecting wire portion 4b, projectingly extending from the diaphragm portion 4a along arrow A in FIG. 3, including a contact region 4c. The diaphragm portion 4a is an example of the “diaphragm” in the present invention.

According to the first embodiment, a lower support layer 5 is formed on the upper surfaces of the etching stopper layer 2 and the polysilicon layer 4. The lower support layer 5, consisting of SiN having an elastic modulus higher than that of polysilicon, has a thickness of about 0.01 μm to about 2 μm. The lower support layer 5 is an example of the “support” in the present invention. An air gap 6 having a height of about 1 μm to about 5 μm is formed between the diaphragm portion 4a and the lower support layer 5.

Another polysilicon layer 7 having a thickness of about 0.1 μm to about 2 μm is formed on the upper surface of the lower support layer 5. This polysilicon layer 7 is doped with an n-type impurity (phosphorus (P)), to be conductive. As shown in FIG. 3, the polysilicon layer 7 includes a discoidal electrode plate portion 7a concentric with the diaphragm portion 4a in plan view and a connecting wire portion 7b, projectingly extending from the electrode plate portion 7a along arrow B in FIG. 3, including a contact region 7c. The electrode plate portion 7a is an example of the “electrode plate” in the present invention.

According to the first embodiment, an upper support layer 8 is formed on the upper surfaces of the lower support layer 5 and the polysilicon layer 7. The upper support layer 8, consisting of SiN having the elastic modulus higher than that of polysilicon, has a thickness of about 0.1 μm to about 2 μm. In other words, the lower and upper support layers 5 and 8 of SiN having the elastic modulus higher than that of polysilicon are formed on the lower and upper surfaces of the electrode plate portion 7a consisting of the polysilicon layer 7 respectively according to the first embodiment.

A plurality of circular sonic holes 9 externally communicating with the air gap 6 are formed in the electrode plate portion 7a of the polysilicon layer 7 and the lower and upper support layers 5 and 8.

As shown in FIG. 1, the lower and upper support layers 5 and 8 are formed with contact holes 5a and 8a in portions corresponding to the contact region 4c of the connecting wire portion 4b of the polysilicon layer 4 respectively. As shown in FIG. 2, a contact hole 8b is formed in a portion of the upper support layer 8 corresponding to the contact region 7c of the connecting wire portion 7b of the polysilicon layer 7.

As shown in FIG. 1, a pad electrode 11 consisting of a gold (Au) layer having a thickness of about 500 nm and a chromium (Cr) layer having a thickness of about 100 nm is formed on the contact region 4c of the connecting wire portion 4b of the polysilicon layer 4 through the contact holes 8a and 5a of the upper and lower support layers 8 and 5. As shown in FIG. 2, another pad electrode 12 consisting of a gold (Au) layer having a thickness of about 500 nm and a chromium (Cr) layer having a thickness of about 100 nm is formed on the contact region 7c of the connecting wire portion 7b of the polysilicon layer 7. The pad electrodes 11 and 12 are examples of the “second pad electrode” and the “first pad electrode” in the present invention respectively.

Operations of the microphone 30 according to the first embodiment are now described with reference to FIGS. 1 and 5. It is assumed that a constant voltage is applied between the diaphragm portion 4a and the electrode plate portion 7a through the pad electrodes 11 and 12.

When the microphone 30 receives no sound, the diaphragm portion 4a remains unvibrational as shown in FIG. 1. Therefore, the electrostatic capacitance between the diaphragm portion 4a and the electrode plate portion 7a remains unchanged, so that no charges move from the diaphragm portion 4a and the electrode plate portion 7a.

When the microphone 30 receives a sound, on the other hand, the diaphragm portion 4a vibrates as shown in FIG. 5. Therefore, the electrostatic capacitance between the diaphragm portion 4a and the electrode plate portion 7a fixed by the lower and upper support layers 5 and 8 so changes that charges move from the diaphragm portion 4a and the electrode plate portion 7a. The microphone 30 outputs this movement of the charges as an electric signal corresponding to the received sound.

According to the first embodiment, as hereinabove described, the lower and upper support layers 5 and 8 of SiN having the elastic modulus higher than that of polysilicon forming the electrode plate portion 7a are formed on the lower and upper surfaces of the electrode plate portion 7a subjected to the maximum tensile stress and the maximum compressive stress upon vibration of the electrode plate portion 7a and the lower and upper support layers 5 and 8 respectively so that bearing strength of the lower and upper support layers 5 and 8 for the electrode plate portion 7a can be further improved as compared with a case of providing a support to cover only the upper or lower surface of an electrode plate, thereby inhibiting the electrode plate portion 7a from vibration. When the microphone 30 receives a sound, therefore, only the diaphragm portion 4a can remarkably vibrate for increasing change in the distance between the diaphragm portion 4a and the electrode plate portion 7a. Consequently, change in the electrostatic capacitance between the diaphragm portion 4a and the electrode plate portion 7a can be so increased as to increase the electric signal output from the microphone 30.

The lower and upper support layers 5 and 8 of SiN having the higher elastic modulus support both of the lower and upper surfaces of the electrode plate portion 7a maximumly expanding or contracting to be subjected to the maximum tensile stress and the maximum compressive stress upon vibration of the electrode plate portion 7a and the lower and upper support layers 5 and 8, whereby the bearing strength of the lower and upper support layers 5 and 8 for the electrode plate portion 7a can be improved also when the total thickness of the lower and upper support layers 5 and 8 formed on the lower and upper surfaces of the electrode plate portion 7a respectively is identical to the thickness of a support formed only on the lower or upper surface of the electrode plate portion 7a. Thus, the bearing strength for the electrode plate portion 7a can be improved without increasing the thicknesses of the lower and upper support layers 5 and 8 dissimilarly to a case of supporting only either the upper surface or the lower surface of an electrode plate with a support, thereby preventing the lower and upper support layers 5 and 8 from cracking resulting from increased thicknesses thereof.

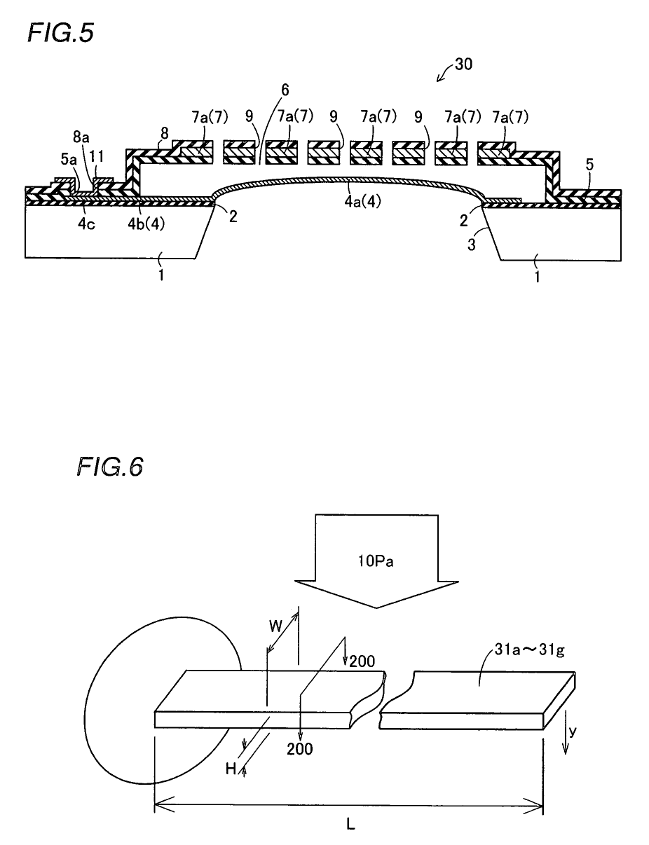

Two simulations performed for confirming effects of the aforementioned first embodiment are now described. In each of the following simulations, a pressure of 10 Pa was downwardly applied onto the upper surface of each of flat plates 31a to 31g shown in FIG. 6 for calculating a downward displacement y (nm) of a second end of each of the flat plates 31a to 31g.

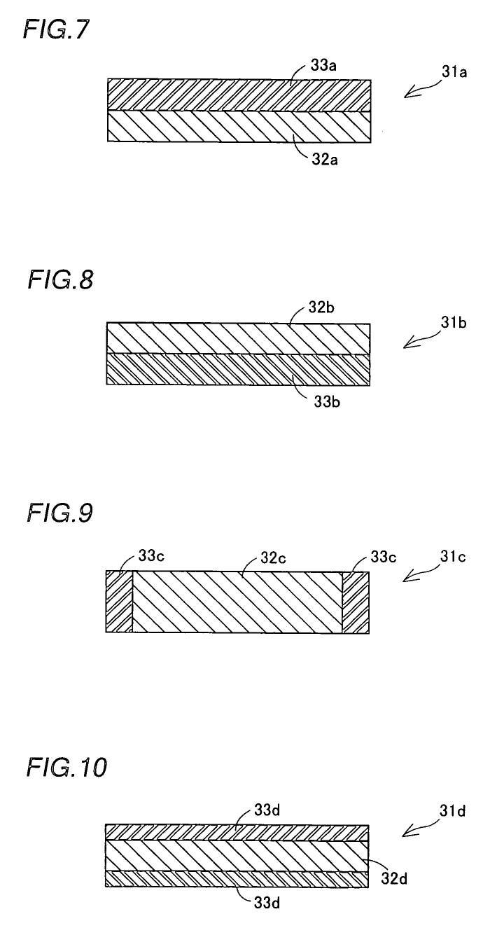

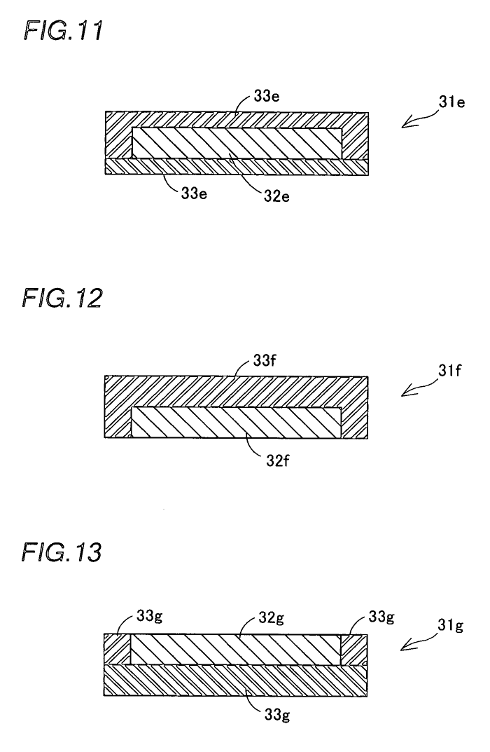

The longitudinal sectional structures of the flat plates 31a to 31g are described with reference to FIGS. 7 to 13. The flat plate 31a shown in FIG. 7 is a model according to comparative 1 prepared by forming a support 33a only on the upper surface of an electrode plate 32a. The flat plate 31b shown in FIG. 8 is a model according to comparative example 2 prepared by forming a support 33b only on the lower surface of an electrode plate 32b. The flat plate 31c shown in FIG. 9 is a model according to comparative example 3 prepared by forming a support 33c only on the side surface of an electrode plate 32. The flat plate 31d shown in FIG. 10 is a model according to Example 1 corresponding to the aforementioned first embodiment prepared by forming supports 33d on the upper and lower surfaces of an electrode plate 32d respectively. The flat plate 31e shown in FIG. 11 is a model according to Example 2 corresponding to a second embodiment, described later, prepared by forming supports 33e on the upper, lower and side surfaces of an electrode plate 32e respectively. The flat plate 31f shown in FIG. 12 is a model according to Example 3 corresponding to a first modification of the present invention, described later, prepared by forming supports 33f on the upper and side surfaces of an electrode plate 32f respectively. The flat plate 31g shown in FIG. 13 is a model according to Example 4 corresponding to a second modification of the present invention, described later, prepared by forming supports 33g on the lower and side surfaces of an electrode plate 32g respectively. It has been assumed that the electrode plates 32a to 32g have elastic moduli of 170 GPa and the supports 33a to 33g have elastic moduli of 300 GPa in all models of the flat plates 31a to 31g.

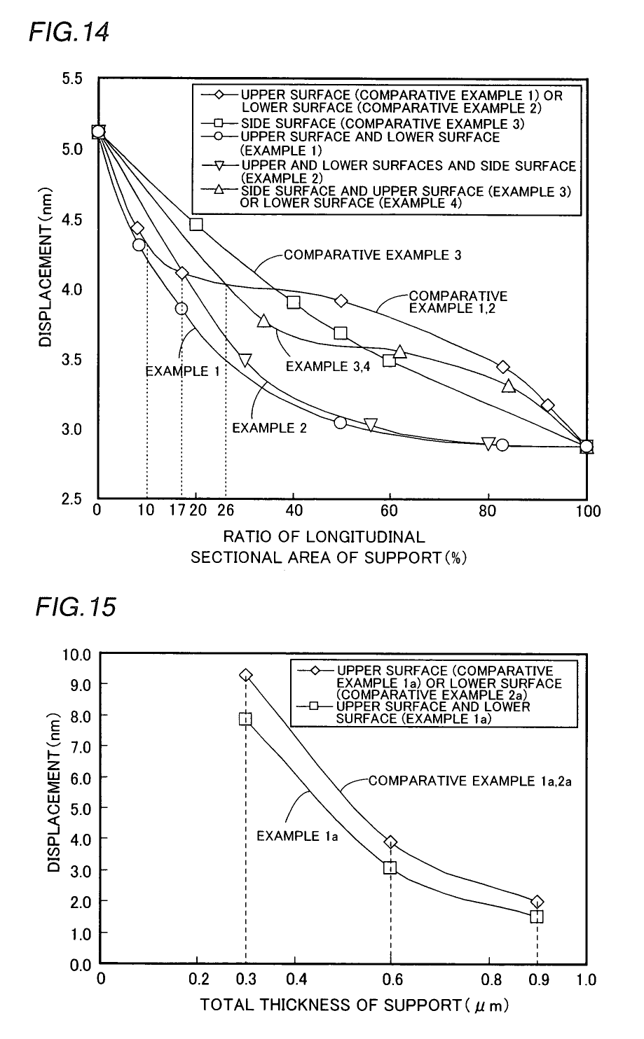

FIG. 14 is a graph showing the relation between the ratios (%) of the longitudinal sectional areas of the supports to the total longitudinal sectional areas (6 μm²) of the electrode plates and the supports and the displacements y (nm). In this simulation, each of the models of the flat plates 31a to 31c and 31d to 31g according to comparative examples 1 to 3 and Examples 1 to 4 had a length L (see FIG. 6) of 100 μm, a width W of 5 μm and a height H of 1.2 μm, while the sum of the longitudinal sectional areas of each of the electrode plates 32a to 32g and each of the supports 33a to 33g was set to a constant value (6 μm²).

The displacements y in the flat plate 31a (see FIG. 7) according to comparative example 1, the flat plate 31b (see FIG. 8) according to comparative example 2 and the flat plate 31d (see FIG. 10) according to Example 1 (corresponding to the first embodiment) are described with reference to FIG. 14. As shown in FIG. 14, it is understood that the displacement y in the flat plate 31d (see FIG. 10) according to Example 1 prepared by forming the supports 33d on the upper and lower surfaces of the electrode plate 32d respectively is smaller than those in the flat plate 31a (see FIG. 7) according to comparative example 1 prepared by forming the support 33a only on the upper surface of the electrode plate 32a and the flat plate 31b (see FIG. 8) according to comparative example 2 prepared by forming the support 33b only on the lower surface of the electrode plate 32b. It is also understood that the displacement y in the flat plate 31d (see FIG. 10) according to Example 1 prepared by forming the supports 33d on the upper and lower surfaces of the electrode plate 32d respectively is further smaller than those in the flat plate 31a (see FIG. 7) according to comparative example 1 prepared by forming the support 33a only on the upper surface of the electrode plate 32a and the flat plate 31b (see FIG. 8) according to comparative example 2 prepared by forming the support 33b only on the lower surface of the electrode plate 32b particularly when the ratios of the longitudinal sectional areas of the supports 33a, 33b and 33d to the total longitudinal sectional areas of the electrode plates 32a, 32b and 32d and the supports 33a, 33b and 33d were set to at least about 10%.

The displacements y in the flat plate 31a (see FIG. 7) according to comparative example 1, the flat plate 31b (see FIG. 8) according to comparative example 2 and the flat plate 31e (see FIG. 11) according to Example 2 (corresponding to the second embodiment) are described with reference to FIG. 14. Table 1 shows the thicknesses of the support (lower layer) 33e, the electrode plate 32e and the support (upper layer) 33e of the flat plate 31e according to Example 2 shown in FIG. 14.

TABLE 1

| Ratio of | Thickness (μm) | | |
|---|---|---|---|
| Support | Support (Lower | Electrode | Support (Upper |
| (%) | Layer) | Plate | Layer) |
| 30 | 0.15 | 0.9 | 0.15 |
| 56 | 0.20 | 0.6 | 0.20 |
| 80 | 0.45 | 0.3 | 0.45 |

As shown in FIG. 14, it is understood that the displacement y in the flat plate 31e (see FIG. 11) according to Example 2 prepared by forming the supports 33e on the upper, lower and side surfaces of the electrode plate 32e respectively is smaller than those in the flat plate 31a (see FIG. 7) according to comparative example 1 prepared by forming the support 33a only on the upper surface of the electrode plate 32a and the flat plate 31b (see FIG. 8) according to comparative example 2 prepared by forming the support 33b only on the lower surface of the electrode plate 32b when the ratios of the longitudinal sectional areas of the supports 33a, 33b and 33e to the total longitudinal sectional areas of the electrode plates 32a, 32b and 32e and the supports 33a, 33b and 33e were set to at least about 17%.

The displacements y in the flat plate 31a (see FIG. 7) according to comparative example 1, the flat plate 31b (see FIG. 8) according to comparative example 2, the flat plate 31f (see FIG. 12) according to Example 3 (corresponding to the first modification) and the flat plate 31g (see FIG. 13) according to Example 4 (corresponding to the second modification) are now described with reference to FIG. 14. As shown in FIG. 14, it is understood that the displacements y in the flat plate 31f (see FIG. 12) according to the first modification prepared by forming the supports 33f on the upper and side surfaces (the overall side surface including a portion closer to the lower surface) of the electrode plate 32f respectively and the flat plate 31g (see FIG. 13) according to the second modification prepared by forming the supports 33g on the lower and side surfaces (the overall side surface including a portion closer to the upper surface) of the electrode plate 32g respectively are smaller than those in the flat plate 31a (see FIG. 7) according to comparative example 1 prepared by forming the support 33a only on the upper surface of the electrode plate 32a and the flat plate 31b (see FIG. 8) prepared by forming the support 33b only on the lower surface of the electrode plate 32b when the ratios of the longitudinal sectional areas of the supports 33a, 33b, 33f and 33g to the total longitudinal sectional areas of the electrode plates 32a, 32b, 32f and 32g and the supports 33a, 33b, 33f and 33g were set to at least about 26%.

When second ends of each electrode plate and each support are vertically displaced, upper and lower surfaces of sections thereof most expand or contract in the longitudinal direction L, so that the maximum tensile stress or the maximum compressive stress acts on the upper and lower surfaces of the sections. However, the lengths of central portions of the sections remain substantially unchanged in the longitudinal direction L upon the vertical displacement of the second ends of the electrode plate and the support, so that tensile stress and compressive stress hardly act on the central portions of the sections. The supports 33d and 33e are formed on the upper and lower surfaces of the electrode plates 32d and 32e respectively in the flat plates 31d and 31e according to Examples 1 and 2 shown in FIGS. 10 and 11 corresponding to the first and second modifications respectively while the supports 33f and 33g are formed on the upper (lower) and side surfaces of the electrode plates 32f and 32g in the flat plates 31f and 31g shown in FIGS. 12 and 13 according to the first and second modifications described later respectively, whereby the displacements y can conceivably be reduced through the elastic supports 33d, 33e, 33f and 33g receiving the maximum tensile stress and the maximum compressive stress when second ends of the electrode plates 32d, 32e, 32f and 32g and the supports 33d, 33e, 33f and 33g are vertically displaced. While the supports 33a and 33b according to comparative examples 1 and 2 formed only on the upper and lower surfaces of the electrode plates 32a and 32b respectively as shown in FIGS. 7 and 8 can receive the maximum tensile stress or the maximum compressive stress acting on the upper and lower surfaces respectively, the electrode plates 32a and 32b having low elastic moduli must receive the maximum tensile stress or the maximum compressive stress acting on the lower and upper surfaces respectively. Therefore, the displacements y are conceivably increased in the flat plates 31a and 31b according to comparative examples 1 and 2.

FIG. 15 is a graph showing the relation between the thicknesses (μm) of supports and displacements y (nm). In this simulation, models of another flat plate 31a (see FIG. 7) according to comparative example 1a, another flat plate 31b (see FIG. 8) according to comparative example 2a and another flat plate 31d (see FIG. 10) according to Example 1a (corresponding to the first embodiment) each having a length L of 100 μm and a width W of 5 μm were employed for varying the total thicknesses of supports 33a, 33b and 33d to 0.3 μm, 0.6 μm and 0.9 μm while setting the thicknesses of electrode plates 32a, 32b and 32d of the flat plates 31a, 31b and 31d to a constant value (0.6 μm). In the model of the flat plate 31d according to Example 1a corresponding to the first embodiment shown in FIG. 10, the thicknesses of the supports 33d formed on the upper and lower surfaces of the electrode plate 32d respectively were equalized to each other (to half the total thickness of the supports 33d). When the total thickness of the supports 33d was 0.3 μm, for example, the thicknesses of the supports 33d formed on the upper and lower surfaces of the electrode plate 32d were set to 0.15 μm respectively.

The displacements y in the flat plate 31a (see FIG. 7) according to comparative example 1a, the flat plate 31b (see FIG. 8) according to comparative example 2a and the flat plate 31d (see FIG. 10) according to Example 1a corresponding to the first embodiment are described with reference to FIG. 15. As shown in FIG. 15, it is understood that the displacement y in the flat plate 31d (see FIG. 10) according to Example 1a corresponding to the first embodiment prepared by forming the supports 33d on both of the upper and lower surfaces of the electrode plate 32d respectively is smaller than those in the flat plate 31a (see FIG. 7) according to comparative example 1a prepared by forming the support 33a only on the upper surface of the electrode plate 32a and the flat plate 31b (see FIG. 8) according to comparative example 2a prepared by forming the support 33b only on the lower surface of the electrode plate 32b when the total thicknesses of the supports 33a, 33b and 33d are in the range of 0.3 μm to 0.9 μm. This means that the flat plate 31d according to Example 1a prepared by forming the supports 33d on both of the upper and lower surfaces of the electrode plate 32d respectively as shown in FIG. 10 can further suppress vibration of the electrode plate 32d as compared with the flat plates 31a and 31b (see FIGS. 7 and 8) according to comparative examples 1a and 2a prepared by forming the supports 33a and 33b only on the upper and lower surfaces of the electrode plates 32a and 32b respectively when the total thicknesses of the supports 33a, 33b and 33d are identical to each other.

It is also understood that the difference between the displacements y in the flat plates 31a and 31b according to comparative examples 1a and 2a shown in FIGS. 7 and 8 respectively and the flat plate 31d according to Example 1a shown in FIG. 10 is larger in the case where the total thicknesses of the supports 33a, 33b an 33d are small (0.3 μm) as compared with the cases where the total thicknesses of the supports 33a, 33b and 33d are large (0.6 μm and 0.9 μm). In other words, it is understood that the displacement y in the flat plate 31d according to Example 1a corresponding to the first embodiment shown in FIG. 10 is further smaller than those in the flat plates 31a and 31b according to comparative examples 1a and 2a shown in FIGS. 7 and 8 respectively when the supports 33a, 33b and 33d are reduced in thickness for miniaturizing corresponding microphones.

A process of manufacturing the microphone 30 according to the first embodiment of the present invention is now described with reference to FIGS. 1 and 16 to 29.

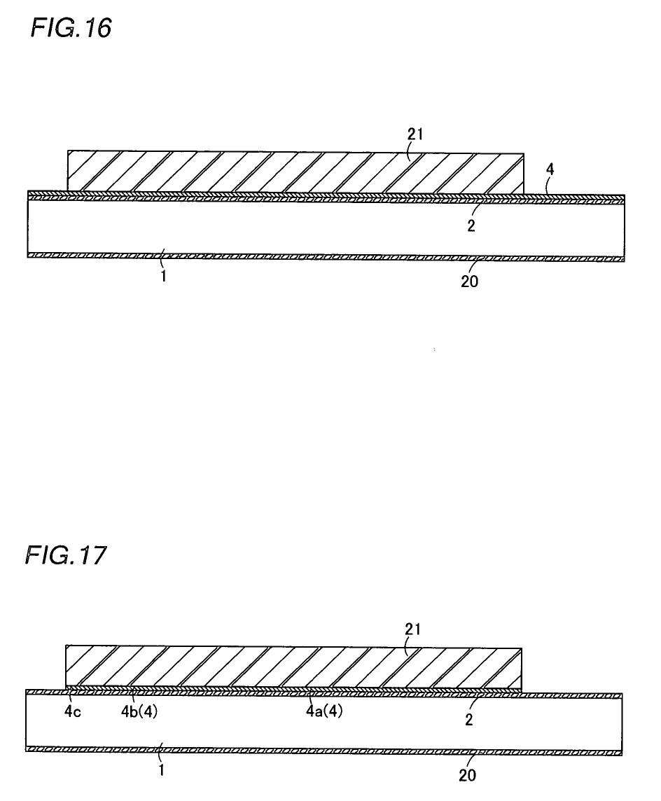

As shown in FIG. 16, the etching stopper layer 2 and a mask layer 20 of SiN each having the thickness of about 0.05 μm to about 0.2 μm are formed on the front and back surfaces of the silicon substrate 1 by LP-CVD (low pressure chemical vapor deposition) with dichlorosilane gas and ammonia gas or monosilane gas and ammonia gas. Thereafter the polysilicon layer 4 having the thickness of about 0.1 μm to about 2.0 μm is formed on the overall upper surface of the etching stopper layer 2 by LP-CVD with monosilane gas or disilane gas. Thereafter solid state phosphorus diffusion is performed with phosphorus oxychloride (POCl₃) under a temperature condition of about 875° C. for converting the polysilicon layer 4 to a high-concentration n⁺ type layer. Thereafter a resist film 21 is formed on a prescribed region of the polysilicon layer 4 by photolithography.

As shown in FIG. 17, the resist film 21 is employed as a mask for patterning the polysilicon layer 4 by dry etching with chloric gas, thereby forming the diaphragm portion 4a and the connecting wire portion 4b. Thereafter the resist film 21 is removed.

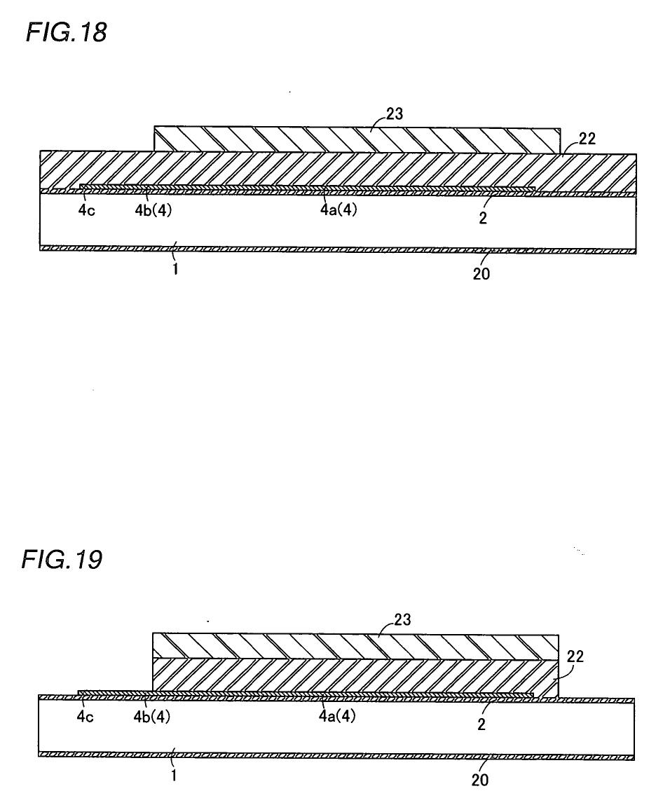

As shown in FIG. 18, a sacrifice layer 22 of PSG (phosphorized SiO₂) having a thickness of about 2 μm to about 5 μm is formed by plasma CVD or atmospheric pressure CVD, to cover the overall surface. Thereafter a resist film 23 is formed on a prescribed region of the sacrifice layer 22 by photolithography.

As shown in FIG. 19, the resist film 23 is employed as a mask for patterning the sacrifice layer 22 for forming the air gap 6 (see FIG. 1) by dry etching with fluoric gas. Thereafter the resist film 23 is removed.

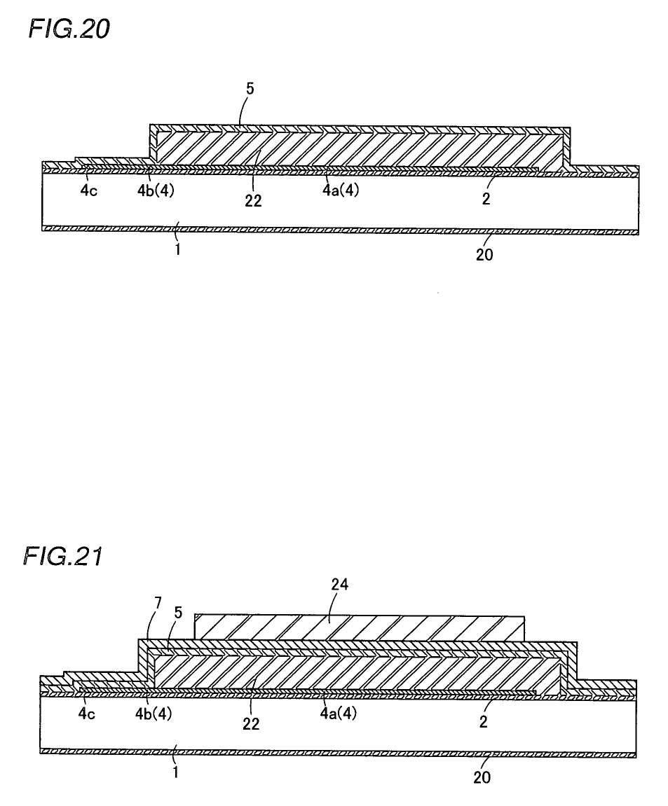

As shown in FIG. 20, the lower support layer 5 of SiN having the thickness of about 0.01 μm to about 2 μm is formed on the upper surfaces of the etching stopper layer 2, the polysilicon layer 4 and the sacrifice layer 22 by LP-CVD with a gas mixture of monosilane and ammonia or dichlorosilane and ammonia.

As shown in FIG. 21, the polysilicon layer 7 having the thickness of about 0.1 μm to about 2 μm is formed on the overall upper surface of the lower support layer 5 by LP-CVD with monosilane gas or disilane gas. Thereafter solid state phosphorus diffusion is performed with phosphorus oxychloride (POCl₃) under a temperature condition of about 875° C. for converting the polysilicon layer 7 to a high-concentration n⁺ type layer. Thereafter a resist film 24 is formed on a prescribed region of the polysilicon layer 7 by photolithography.

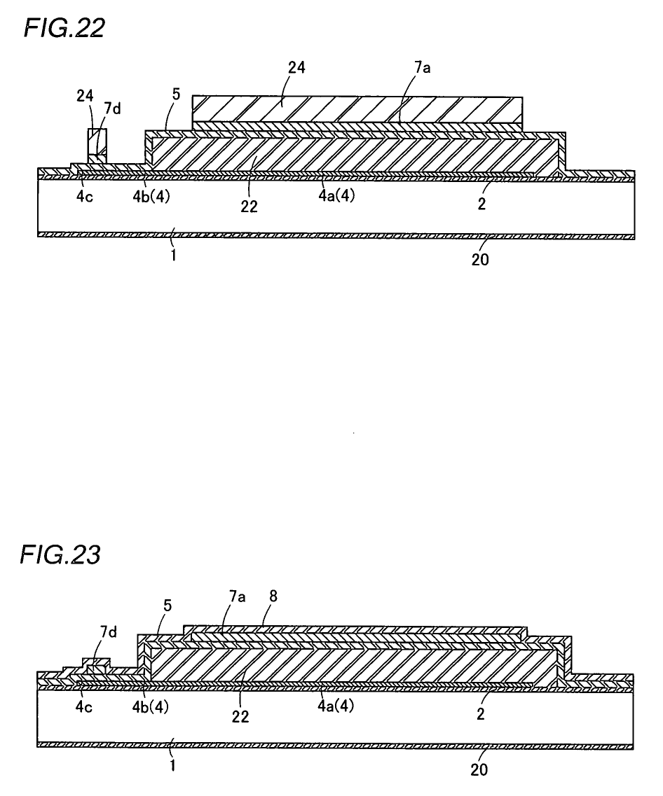

As shown in FIG. 22, the resist film 24 is employed as a mask for patterning the polysilicon layer 7 into a polysilicon layer 7d to be formed with the electrode plate portion 7a, the connecting wire portion 7b (see FIG. 3) and the pad electrode 11 by etching with chloric gas. Thereafter the resist film 24 is removed.

As shown in FIG. 23, the upper support layer 8 of SiN having the thickness of about 0.1 μm to about 2 μm is formed on the upper surfaces of the lower support layer 5, the electrode plate portion 7a and the connecting wire portion 7b by LP-CVD with a gas mixture of monosilane and ammonia or dichlorosilane and ammonia or plasma CVD.

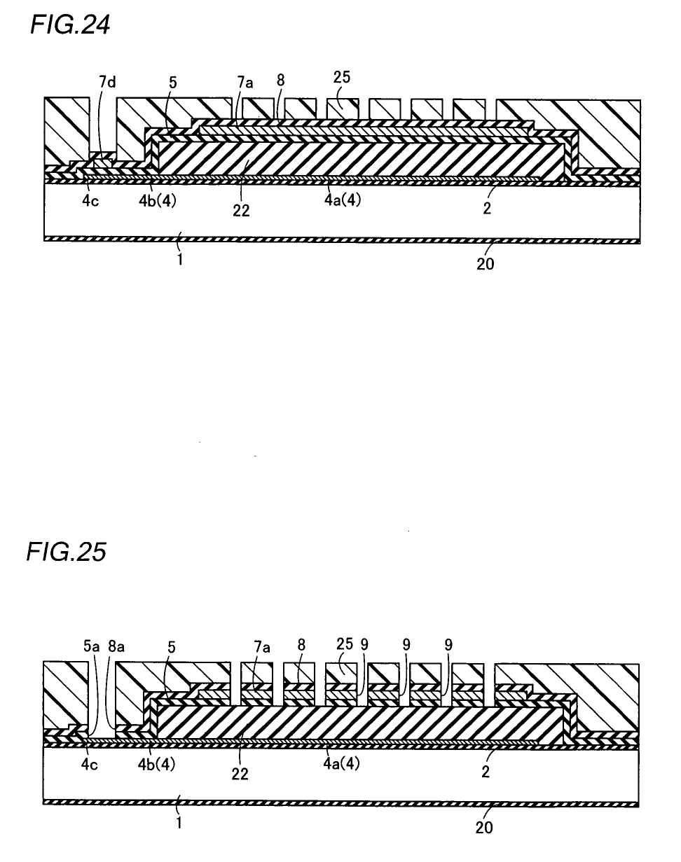

As shown in FIG. 24, resist films 25 are formed on prescribed regions of the upper support layer 8 by photolithography.

As shown in FIG. 25, the resist films 25 are employed as masks for patterning the upper support layer 8 by etching with a gas mixture of argon, oxygen and CF₄. Thereafter the same resist films 25 are employed as masks for patterning the polysilicon layer 7 by etching with a gas mixture of chlorine and oxygen. The polysilicon layer 7d is simultaneously removed by etching. Thereafter the same resist films 25 are employed as masks for patterning the lower support layer 5 by etching with a gas mixture of argon, oxygen and CF₄. Thus, the contact holes 5a and 8a and the sonic holes 9 are formed as shown in FIG. 25. Thereafter the resist films 25 are removed. Then, a resist film (not shown) covering a region other than that for forming the contact hole 8b (see FIG. 2) is formed by photolithography and employed as a mask for patterning the upper support layer 8 by etching with a gas mixture of argon, oxygen and CF₄, thereby forming the contact hole 8b.

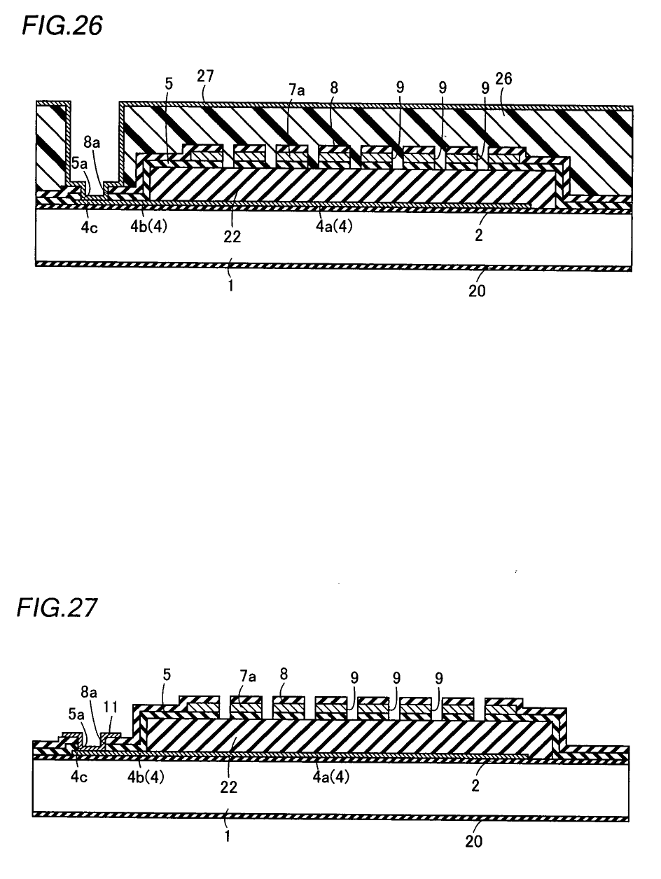

As shown in FIG. 26, a resist film 26 is formed by photolithography to cover a region other than those for forming the pad electrodes 11 and 12, for thereafter forming an electrode layer 27 of a gold (Au) layer having a thickness of about 500 nm and a chromium (Cr) layer having a thickness of about 100 nm on the overall surface by evaporation. Then, portions of the electrode layer 27 formed on the upper and side surfaces of the resist film 26 are removed by removing the resist film 26 by a lift-off method, thereby forming the pad electrodes 11 and 12 (see FIGS. 1 to 3) as shown in FIG. 27.

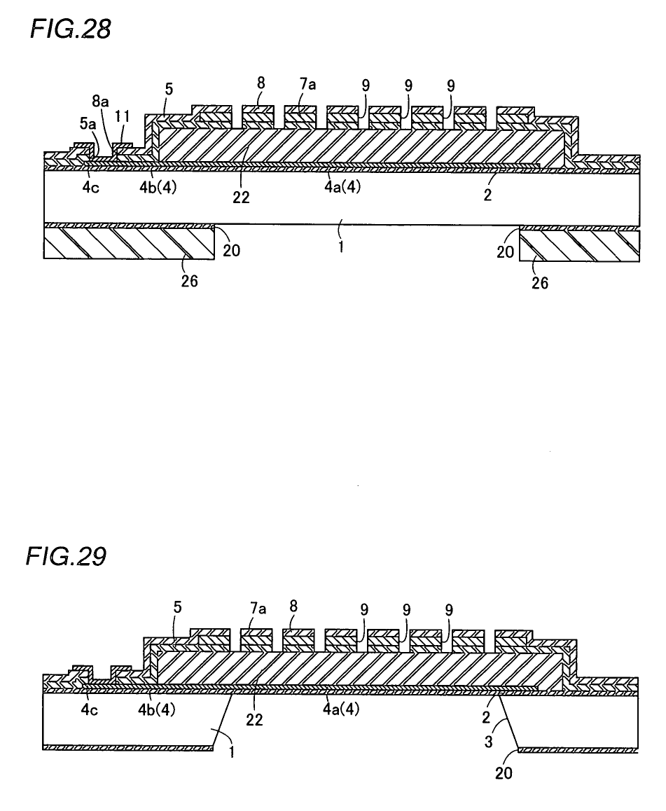

As shown in FIG. 28, other resist films 26 are formed on prescribed regions of the surface of the mask layer 20 by photolithography. Thereafter the resist films 26 are employed as masks for patterning the mask layer 20 by dry etching with fluoric gas. Thereafter the resist films 26 are removed.

As shown in FIG. 29, the opening 3 is formed in the silicon substrate 1 by anisotropic wet etching employing an aqueous solution of tetramethyl ammonium hydroxide (TMAH) or an aqueous solution of potassium hydroxide (KOH) through the mask layer 20.

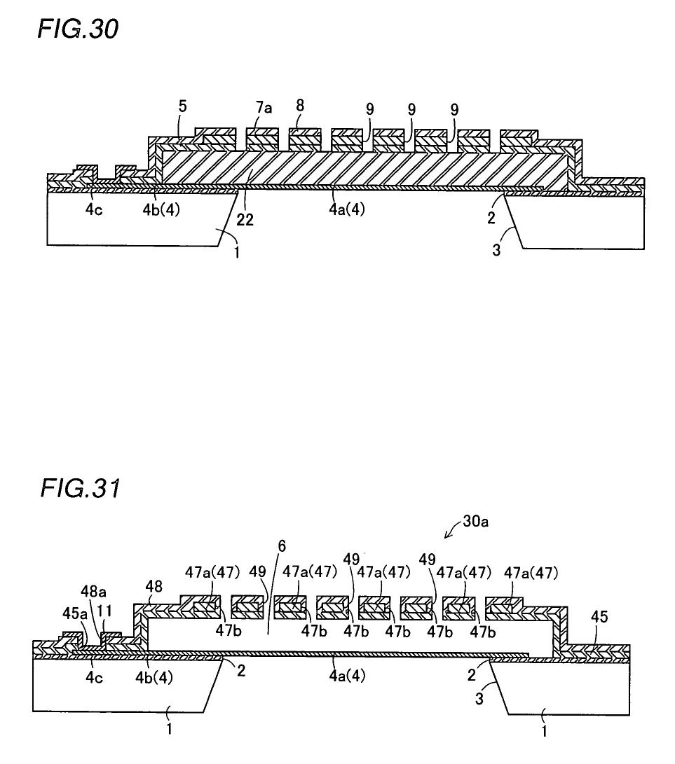

As shown in FIG. 30, the mask layer 20 is removed and part of the etching stopper layer 2 exposed through the opening 3 is etched by dry etching with fluoric gas. Thereafter the sacrifice layer 22 is removed by introducing hydrofluoric acid through the sonic holes 9 for forming the air gap 6, thereby completing the microphone 30 according to the first embodiment shown in FIG. 1.

### Second Embodiment

Referring to FIG. 31, supports are formed not only on the upper and lower surfaces of an electrode plate portion 47a but also on the inner side surfaces of holes 47b of the electrode plate portion 47a corresponding to sonic holes 49 in a microphone 30a according to a second embodiment of the present invention, dissimilarly to the aforementioned first embodiment.

In the microphone 30a according to the second embodiment, the holes 47b larger than the sonic holes 49 are formed in the electrode plate portion 47a of a polysilicon layer 47 on positions corresponding to the sonic holes 49, as shown in FIG. 31. An upper support layer 48 is so formed as to cover not only the upper surface of the electrode plate portion 47a of the polysilicon layer 47 but also the side surfaces of the holes 47b of the electrode plate portion 47a. A lower support layer 45 is so formed as to cover portions of the polysilicon layer 47 located on the lower ends of the inner side surfaces of the holes 47b. In other words, the upper and lower support layers 48 and 45 form the side surfaces of the sonic holes 49.

The microphone 30a according to the second embodiment is identical in structure to the microphone 30 according to the aforementioned first embodiment, except the lower support layer 45, the polysilicon layer 47 and the upper support layer 48.

According to the second embodiment, as hereinabove described, the lower and upper support layers 45 and 48 of SiN having the elastic modulus higher than that of polysilicon forming the electrode plate portion 47a are formed on the lower and upper surfaces of the electrode plate 47a subjected to the maximum tensile stress and the maximum compressive stress upon vibration of the electrode plate portion 47a and the lower and upper support layers 45 and 48 and the side surfaces of the holes 47b of the electrode plate portion 47a corresponding to the sonic holes 49 so that bearing strength of the lower and upper support layers 45 and 48 for the electrode plate portion 47a can be improved as compared with a case of providing a support so formed as to cover only the upper or lower surface of an electrode plate, thereby inhibiting the electrode plate portion 47a from vibration. This point has already been confirmed in the simulation shown in FIG. 14.

A process of manufacturing the microphone 30a according to the second embodiment of the present invention is now described with reference to FIGS. 31 and 32 to 36.

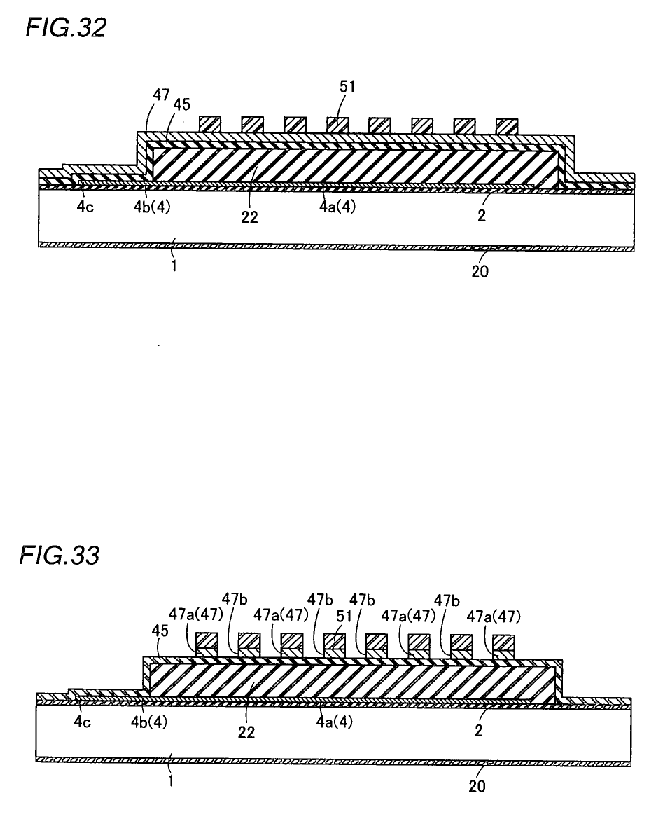

First, a configuration similar to that shown in FIG. 21 is formed through steps similar to those in the first embodiment shown in FIGS. 16 to 20, and the polysilicon layer 47 having a thickness of about 0.1 μm to about 2.0 μm is formed on the upper surface of the lower support layer 45 by CVD with monosilane gas or disilane gas, as shown in FIG. 32. Thereafter resist films 51 are formed on prescribed regions of the polysilicon layer 47 by photolithography.

As shown in FIG. 33, the resist films 51 are employed as masks for patterning the polysilicon layer 47 by etching with a gas mixture of chlorine and oxygen, thereby forming the electrode plate portion 47a including the holes 47b larger in diameter than the sonic holes 49 and a connecting wire portion (not shown). Thereafter the resist films 51 are removed.

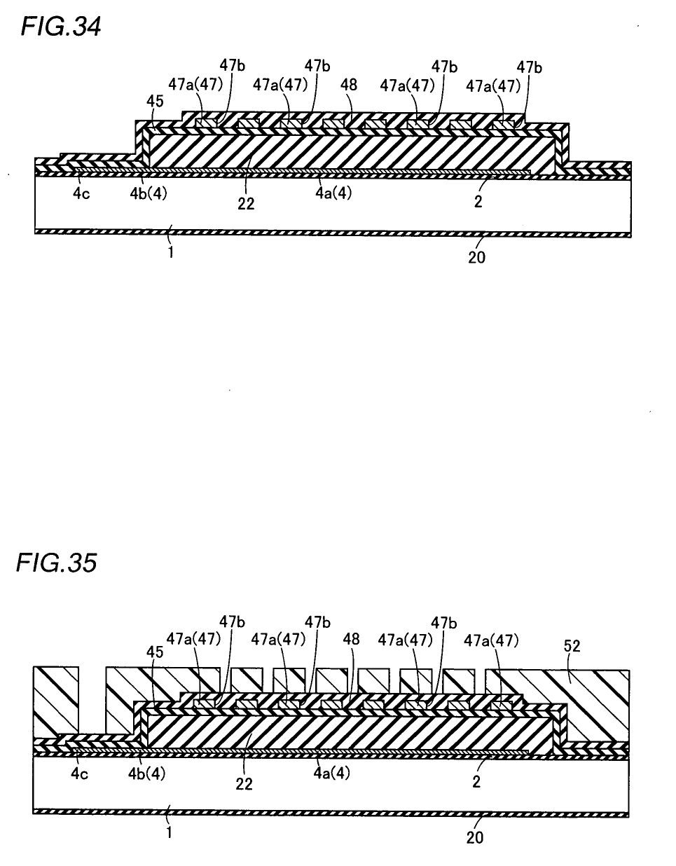

As shown in FIG. 34, the upper support layer 48 of SiN having a thickness of about 0.01 μm to about 2.0 μm is formed by LP-CVD with a gas mixture of monosilane gas and ammonia gas or dichlorosilane gas and ammonia gas.

As shown in FIG. 35, resist films 52 are formed on prescribed regions of the upper support layer 48 by photolithography.

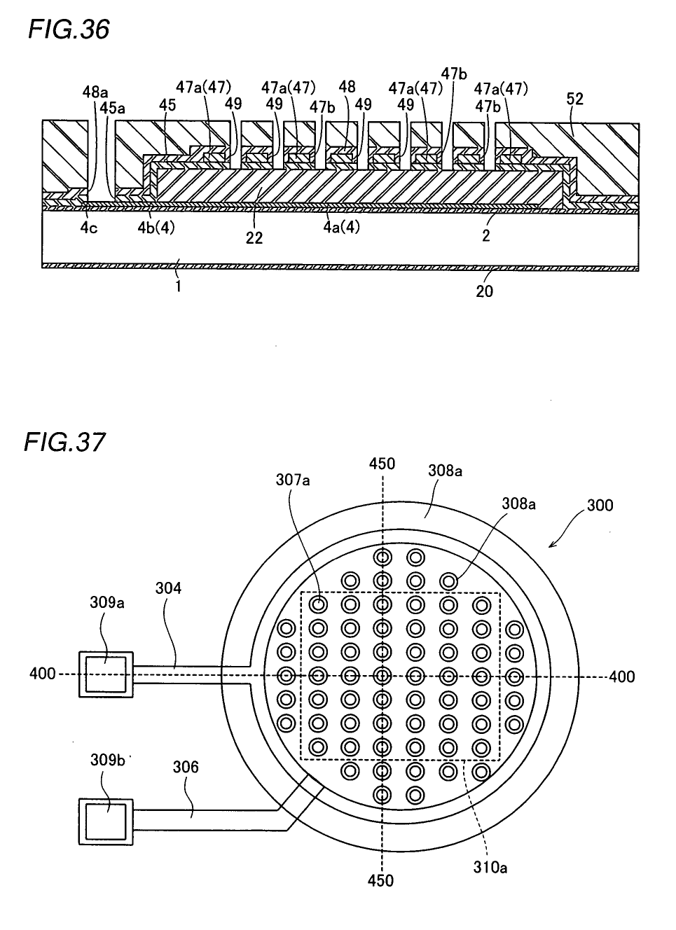

Then, the resist films 52 are employed as masks for etching the upper and lower support layers 48 and 45 with a gas mixture of argon, oxygen and CF₄. Thus, a configuration including the sonic holes 49 and contact holes 45a and 48a is formed as shown in FIG. 36. Thereafter the resist films 52 are removed.

Then, the microphone 30a according to the second embodiment shown in FIG. 31 is completed through steps similar to those of the first embodiment shown in FIGS. 26 to 30.

### Third Embodiment

A sonic sensor 300 according to a third embodiment of the present invention is described with reference to FIGS. 37 to 39. According to the third embodiment, modified SiOC layers 308a formed by ion implantation are employed as supports supporting electrode plates (fixed electrodes), dissimilarly to the aforementioned first and second embodiments.

As shown in FIGS. 37 to 39, the sonic sensor 300 according to the third embodiment comprises a vibrating electrode 304 constituting a diaphragm formed on a silicon substrate 301 and fixed electrodes 306 opposed to the vibrating electrode 304 and arranged at prescribed intervals. The vibrating electrode 304 and the fixed electrodes 306 constitute capacitors.

The sonic sensor 300 includes the silicon substrate 301, an etching stopper layer 302a, the vibrating electrode 304, a sacrifice layer 305, the fixed electrodes 306, sonic holes 307a, the modified SiOC layers 308a, a pad electrode 309a for the vibrating electrode 304, another pad electrode 309b for the fixed electrodes 306, a substrate opening 310a and an air gap 311.

The silicon substrate 301 is an example of the “semiconductor substrate” in the present invention, and the vibrating electrode 304 is an example of the “first electrode” or the “diaphragm” in the present invention. The fixed electrodes 306 are examples of the “second electrode” or the “electrode plate” in the present invention, and the modified SiOC layers 308a are examples of the “insulating film”, the “insulating film, containing the impurity, containing Si, O and C” or the “support” in the present invention.

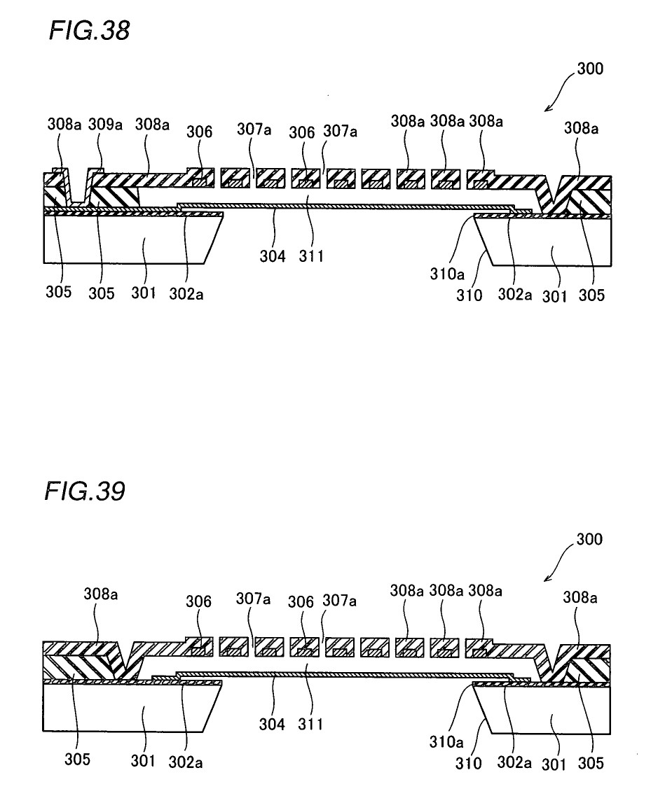

The silicon substrate 301 serves as the substrate of the sonic sensor 300. This silicon substrate 301 is provided with a sound hole (opening) 310 passing through the silicon substrate 301 from above, as shown in FIGS. 38 and 39. The substrate opening 310a of the sound hole 310 has a square shape in plan view on the upper surface of the silicon substrate 301, as shown in FIG. 37. The etching stopper layer 302a is formed on the upper surface of the silicon substrate 301.

The vibrating electrode 304 is so formed as to cover the sound hole 310 of the silicon substrate 301, as shown in FIGS. 38 and 39. The vibrating electrode 304 serving as the diaphragm vibrates through a sound pressure transmitted from under the sound hole 310. More specifically, the vibrating electrode 304, formed in a floating state in a region covering the sound hole 310, is fixed onto the silicon substrate 301 (etching stopper layer 302a) on the outer peripheral region of the sound hole 310.

As shown in FIGS. 38 and 39, the fixed electrodes 306 provided above the vibrating electrode 304 form the capacitors along with the vibrating electrode 304. When the vibrating electrode 304 vibrates by the sound pressure, the electrostatic capacitances of these capacitors change. The fixed electrodes 306 are so sized as to at least partially occupy the substrate opening 310a (sound hole 310).

The modified SiOC layers 308a, so formed as to cover the fixed electrodes 306 as shown in FIGS. 38 and 39, are provided for fixing the fixed electrodes 306 to the silicon substrate 301 on the outer peripheries of the fixed electrodes 306. The modified SiOC layers 308a are prepared by ion-implanting an impurity such as boron (B) into an SiOC layer having a composition SiOₓ(CH₃)_{y}, an insulating film having a low dielectric constant.

The sacrifice layer 305 is so formed as to insulate the vibrating electrode 304 and the fixed electrodes 306 from each other, as shown in FIGS. 38 and 39. A space formed by the modified SiOC layers 308a and the fixed electrodes 306 between the same and the vibrating electrode 304 is referred to as the air gap 311. The modified SiOC layers 308a and the fixed electrodes 306 form the plurality of sonic holes 307a.

The pad electrodes 309a and 309b for the vibrating electrode 304 and the fixed electrodes 306 are connected to the vibrating electrode 304 and the fixed electrodes 306 respectively. These pad electrodes 309a and 309b are provided for applying prescribed voltages to the vibrating electrode 304 and the fixed electrodes 306 respectively. When the electrostatic capacitances of the capacitors formed by the vibrating electrode 304 and the fixed electrodes 306 change, the potential difference between the pad electrodes 309a and 309b for the vibrating electrode 304 and the fixed electrodes 306 also changes so that the sonic sensor 300 outputs the changing potential difference as a sound signal. In other words, the pad electrodes 309a and 309b for the vibrating electrode 304 and the fixed electrodes 306 indirectly detect the change in the electrostatic capacitances of the capacitors. The sonic sensor 300 outputs the sound signal through a speaker, or coverts the same to a digital signal and stores the digital signal, for example.

Table 2 shows the film characteristics (residual stress, BHS etching rate and dielectric constant) of the modified SiOC layers 308a. The residual stress (internal stress) includes stress (tensile stress) acting in a contractive direction with respect to an underlayer and stress (compressive stress) acting in an expansive direction with respect to the underlayer. Referring to Table 2, plus values show compressive stress while a minus value shows tensile stress.

TABLE 2

| | | | BHF Etching | Dielectric |
|---|---|---|---|---|
| Film Type | Residual Stress (MPa) | | Rate (nm/min) | Constant |
| SiN | 100˜200 | Compressive | 8.7 | 7 |
| | | Stress | | |
| SiO₂ | 100˜200 | Compressive | 82 | 4.2 |
| | | Stress | | |
| SiOC | −50 | Tensile Stress | 0.1 | 3.0 |
| Modified SiOC | 400 | Compressive | 0.1 | 3.7 |
| | | Stress | | |

The insulating films fixing the fixed electrodes 306 have compressive stress to pull the fixed electrodes 306 toward the outer peripheries (expansive direction with respect to underlayers). Therefore, the insulating films can strongly pull the fixed electrodes 306 as the compressive stress is increased.

As clearly understood from Table 2, a modified SiOC layer has compressive stress reverse to tensile stress of an unmodified SiOC layer, and this compressive stress is approximately twice as much as that of a silicon nitride film (SiN) or a silicon oxide film (SiO₂). This is because the modified SiOC layer (prepared by ion-implanting an impurity into an SiOC layer) causes compressive stress (stress acting in an expansive direction with respect to an underlayer) due to film densification through ion implantation and subsequent expansion.

According to the first embodiment, the modified SiOC layers 308a having high compressive stress fix the fixed electrodes 306 in an outwardly pulled state (in an expansive direction with respect to underlayers). When subjected to a sound pressure, therefore, the fixed electrodes 306 are inhibited from vibration (displacement). Consequently, noise applied to a sonic signal is reduced as compared with a case of employing SiOC layers containing no impurity, whereby the sonic sensor 300 can correctly measure capacitance change with low noise.

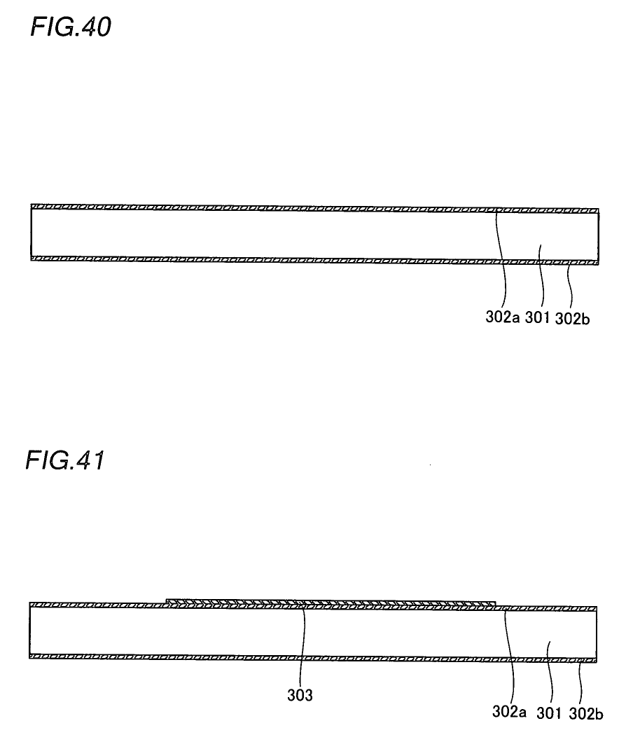

A method of manufacturing the sonic sensor 300 according to the third embodiment of the present invention is now described with reference to FIGS. 40 to 51. FIGS. 40 to 51 are sectional views taken along the line 400-400 in FIG. 37, similarly to FIG. 38.

As shown in FIG. 40, etching stopper layers 302a and 302b are formed on the silicon substrate 301, having both surfaces polished, by low-pressure CVD with thicknesses of about 200 nm. The etching stopper layer 302b serves as a mask for an operation of etching the silicon substrate 301 from the back surface, while the etching stopper layer 302a serves as a stopper for the operation of etching the silicon substrate 301 from the back surface. The etching stopper layers 302a and 302b are generally formed by silicon nitride films (SiN films). The silicon nitride films (SiN films) are formed by gas such as monosilane and ammonia or dichlorosilane and ammonia at a film forming temperature of 300° C. to 600° C.

As shown in FIG. 41, a sacrifice layer 303 having a thickness of about 500 nm is formed on the overall surface of the etching stopper layer 302a by plasma CVD or atmospheric pressure CVD. The sacrifice layer 303, generally formed by a silicon oxide film containing phosphorus (P), may alternatively be formed by any film so far as the same is soluble in hydrofluoric acid (HF). This sacrifice layer 303 is removed later by etching with HF, not to remain in the final structure. Thereafter unnecessary portions of the sacrifice layer 303 are removed by ordinary photolithography and etching.

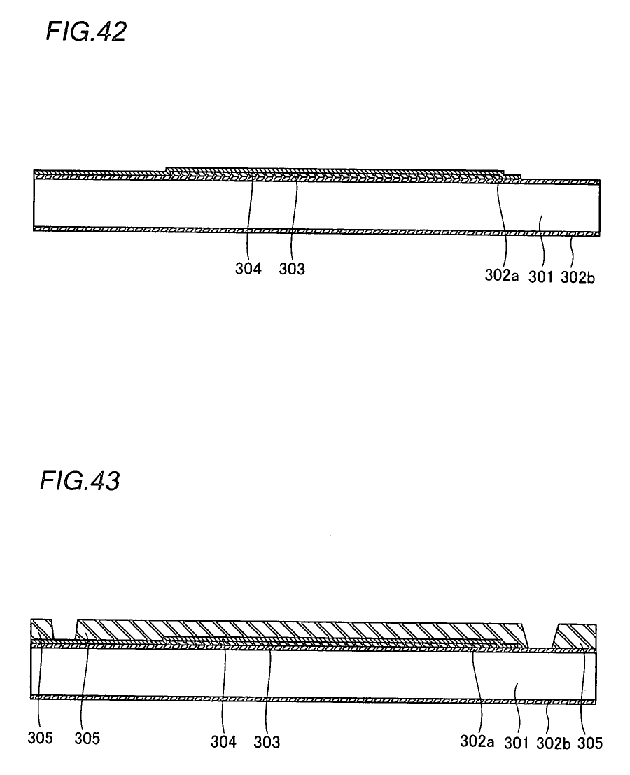

As shown in FIG. 42, the vibrating electrode 304 is formed on the overall surfaces of the etching stopper layer 302a and the sacrifice layer 303 with a thickness of about 1 μm. The vibrating electrode 304, generally prepared from polysilicon, may alternatively be made of another conductive material. Unnecessary portions of the vibrating electrode 304 are removed by ordinary photolithography and etching.

As shown in FIG. 43, the sacrifice layer 305 having a thickness of about 3 μm is formed on the vibrating electrode 304. The sacrifice layer 305, generally formed by a silicon oxide film containing phosphorus (P) similarly to the sacrifice layer 303, may alternatively be formed by any film so far as the same is soluble in hydrofluoric acid (HF). A portion of the sacrifice layer 305 for forming the air gap 311 (see FIG. 38) in a later step is removed later by etching with HF, not to remain in the final structure. The sacrifice layer 305 remaining in the final structure functions as an insulating layer insulating the vibrating electrode 304 and the fixed electrodes 306 from each other. Peripheral portions of the sacrifice layer 305 are removed by ordinary photolithography and etching, so that the sacrifice layer 305 has openings. The thickness of the sacrifice layer 305, corresponding to the final interelectrode air gap distance, is reflected on the capacitance (C=e×S/t, where e represents the dielectric constant, S represents the electrode area and t represents the air gap distance) as well as on sensitivity. The thickness of the sacrifice layer 305 also remarkably influences firmness of the structure of the sonic sensor 300. If the air gap 311 is too narrow, for example, the vibrating electrode 304 and the fixed electrodes 306 disadvantageously come into contact with each other, to prevent the sonic sensor 300 from sensing.

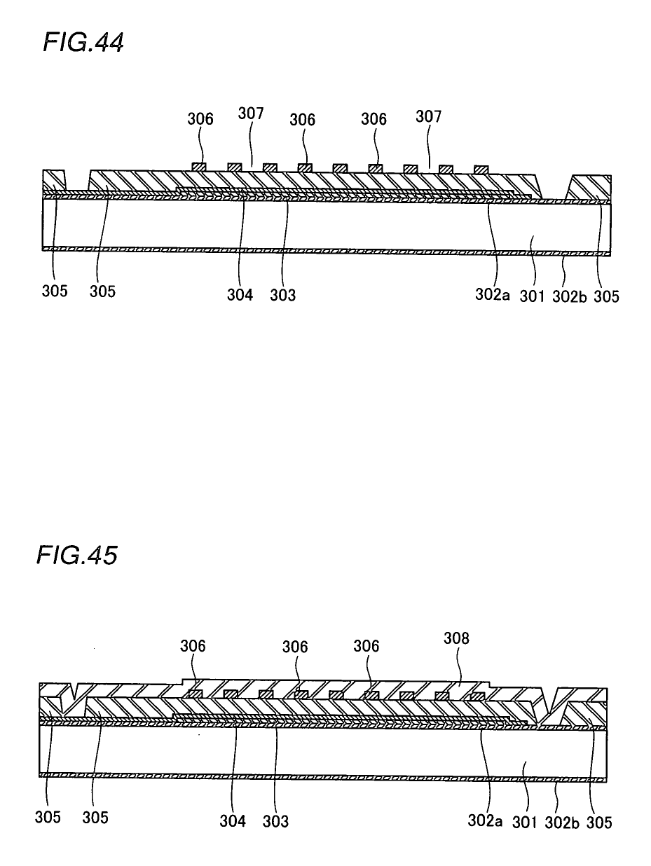

As shown in FIG. 44, conductive films for forming the fixed electrodes 306 are provided on the sacrifice layer 305. These conductive films are preferably prepared from polysilicon, in view of mechanical strength. Unnecessary portions of the conductive films are removed by ordinary photolithography and etching. In this patterning, sonic holes 307 are simultaneously formed so that air in the air gap 311 moves in response to a displacement of the vibrating electrode 304.

As shown in FIG. 45, an SiOC layer 308 prepared from an insulating film containing Si, O and C is formed on the fixed electrodes 306 and the sacrifice layer 305 by plasma CVD with a thickness of about 2 μm. This SiOC layer 308 is formed with a gas mixture of trimethylsilane and oxygen under conditions of a film forming temperature of about 350° C., a film forming pressure of about 4.0 Torr and high-frequency power of about 600 W. Thus, the SiOC layer 308 exhibits a low dielectric constant with a composition SiOₓ(CH₃)_{y}.

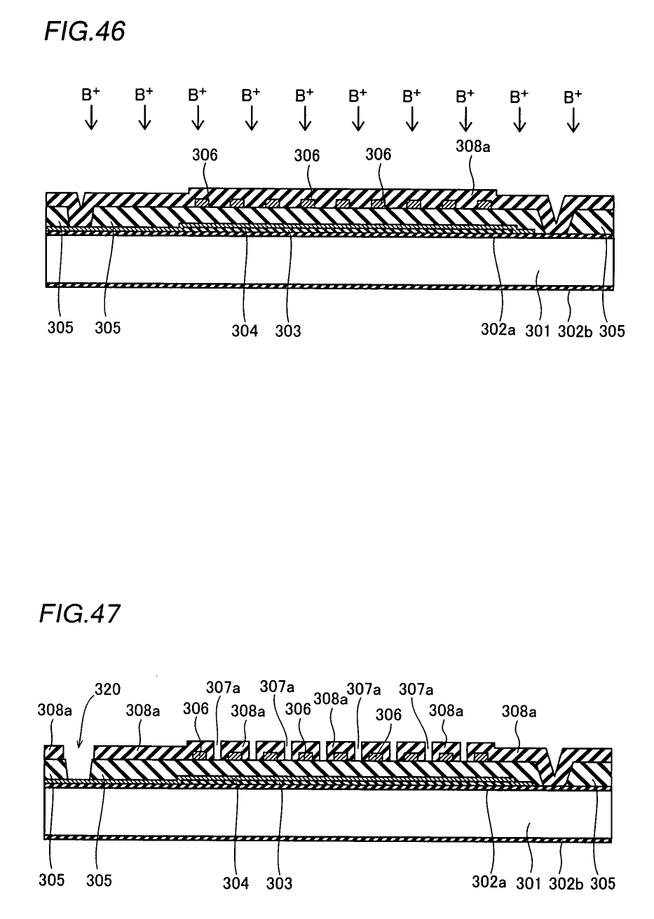

As shown in FIG. 46, ion implantation is performed for modifying the SiOC layer 308. In this ion implantation, boron ions (B⁺) are implanted under conditions of implantation energy of about 140 keV and an implantation rate of about 2×10¹⁵ cm⁻², thereby forming the modified SiOC layers 308 containing boron.

During the ion implantation of the impurity, the temperature of the SiOC layer 308 is substantially increased to about 800° C., so that the SiOC layer 308 is densified. At this time, the SiOC layer 308 is densified while bonds therein are cut due to the implanted impurity, so that the SiOC layer 308 is relieved from stress. When returning from the temperature of about 800° C. to an equilibrium state of the room temperature after the ion implantation, the SiOC layer 308 develops expansive force to result in compressive stress (stress acting in an expansive direction with respect to the underlayer) as film stress, thereby forming the modified SiOC layers 308a having high compressive stress.

Boron ions are introduced into the SiOC layer 308 by ion implantation for improving adhesiveness between the fixed electrodes 306 and the modified SiOC layers 308a due to mixing action on the interfaces therebetween, so that the modified SiOC layers 308a fix the fixed electrodes 306 in a strongly pulled state. Thus, noise resistance with respect to the sonic signal is further improved.

As shown in FIG. 47, unnecessary portions of the modified SiOC layers 308a are removed by ordinary photolithography and etching. The unnecessary portions include not only peripheral portions but also a pad portion 320 and the sonic holes 307a. In this patterning of the modified SiOC layers 308a, the sonic holes 307a smaller in diameter than the sonic holes 307 are simultaneously formed in alignment with the precedently formed sonic holes 307. Thus, the modified SiOC layers 308a also cover the side walls of the fixed electrodes 306, thereby more strongly fixing the fixed electrodes 306.

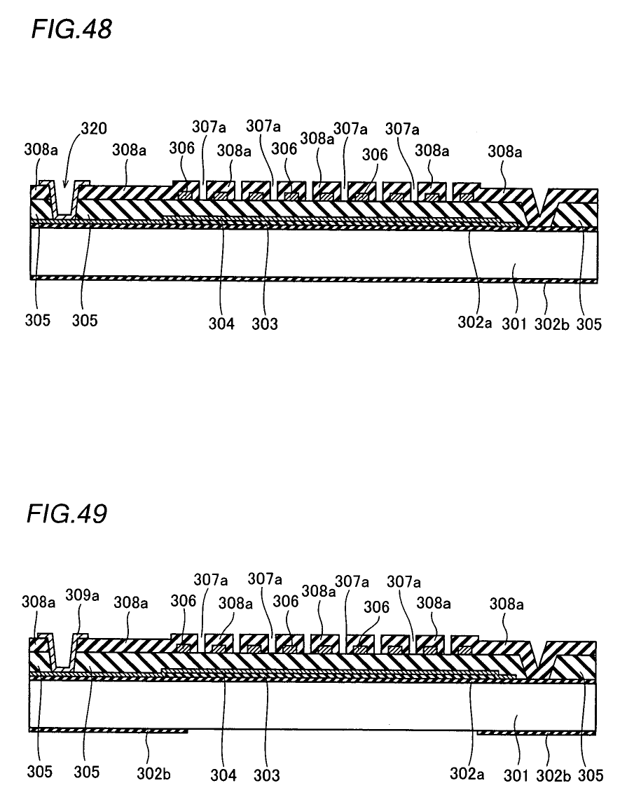

As shown in FIG. 48, the pad electrodes 309a and 309b (see FIG. 37) for the vibrating electrode 304 and the fixed electrodes 306 are formed on the pad portion 320. Low-resistance metal films of aluminum, copper or gold are particularly suitable as the materials for the pad electrodes 309a and 309b for the vibrating electrode 304 and the fixed electrodes 306. The pad electrodes 309a and 309b for the vibrating electrode 304 and the fixed electrodes 306, which may be formed by ordinary photolithography and etching, may alternatively be formed by the so-called plated resist method or a resist etch-off method.

As shown in FIG. 49, unnecessary portions of the etching stopper layer 302b provided on the back surface of the silicon substrate 301 are removed by ordinary photolithography and etching.

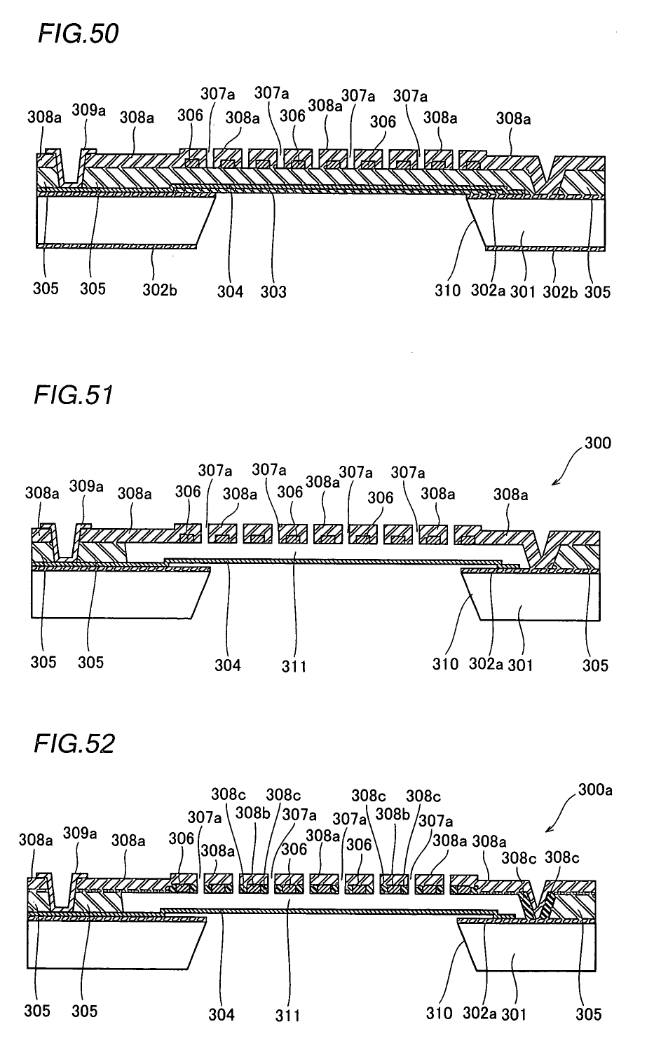

As shown in FIG. 50, the patterned etching stopper layer 302b is employed as a mask for performing anisotropic etching with an alkaline etching solution such as an aqueous solution of potassium hydroxide (KOH) or an aqueous solution of tetramethyl ammonium hydroxide (TMAH). The etching stopper layer 302a formed in the step shown in FIG. 40 automatically stops this anisotropic etching. Thus, the opening (sound hole) 310 is formed in the silicon substrate 301.

As shown in FIG. 51, the portion of the etching stopper layer 302a remaining in the opening 310 is removed from the back surface of the silicon substrate 301 with an etching solution (phosphoric acid, for example) or by dry etching. Thereafter the sacrifice layer 303 is removed with HF through the back surface of the silicon substrate 301, while the sacrifice layer 305 is selectively removed by etching from the side of the sonic holes 307a, thereby finally forming the air gap 311.

### Fourth Embodiment

Referring to FIG. 52, insulating films fixing fixed electrodes 306 are constituted of multilayer films of SiOC layers 308c and modified SiOC layers 308b in a sonic sensor 300a according to a fourth embodiment of the present invention, dissimilarly to the aforementioned third embodiment.

In the sonic sensor 300a according to the fourth embodiment, the multilayer films can be easily formed by exercising control for reducing a modification depth by reducing energy for implanting an impurity into an SiOC layer 308 in a step similar to that of the third embodiment shown in FIG. 46. According to the fourth embodiment, the implantation energy is set to 100 keV, for example.

The modified SiOC layers 308b are examples of the “first region” in the present invention, and the SiOC layers 308c are examples of the “second region” in the present invention.

As understood from Table 2, an unmodified SiOC layer exhibiting tensile stress as residual stress cannot fix the fixed electrodes 306 in a pulled state, while the same exhibits a dielectric constant of 3.0 lower than that of a silicon oxide film (dielectric constant: 4.2) or a silicon nitride film (dielectric constant: 7). According to the fourth embodiment, the insulating films fixing the fixed electrodes 306 include the modified SiOC layers 308b containing an impurity introduced by ion implantation for fixing the fixed electrodes 306 in an outwardly pulled state, thereby inhibiting the fixed electrodes 306 from vibration (displacement) resulting from propagation of a sound wave or the like. Further, the modified SiOC layers 308b densified by ion implantation exhibit a dielectric constant higher than that before ion implantation, whereby the dielectric constant of the insulating films, including the SiOC layers 308b containing no impurity, fixing the fixed electrodes 306 can be reduced as compared with that of the supports according to the third embodiment constituted of only the modified SiOC layers 308a. Consequently, a parasitic capacitance added to the electrostatic capacitances between a vibrating electrode 304 and the fixed electrodes 306, i.e., the parasitic capacitance (≈dielectric constant of material×area/thickness) resulting from the insulating films (the modified SiOC layers 308b and the SiOC layers 308c) fixing the fixed electrodes 306 can be so reduced as to improve sensitivity (≈bias voltage×electrostatic capacitance change resulting from vibration/electrostatic capacitance) of the sonic sensor 300a.

As understood from Table 2, further, the SiOC layers 308c and the modified SiOC layers 308b exhibit smaller etching rates of BHF (buffered hydrofluoric acid) as compared with a silicon oxide film or a silicon nitride film. Therefore, film loss resulting from HF treatment for removing sacrifice layers 303 and 305 is so suppressed as to attain an effect identical to that obtained by substantially increasing the thickness of the insulating films fixing the fixed electrodes 306. Consequently, the insulating films can fix the fixed electrodes 306 in a more strongly pulled state. Thus, a process margin is increased in a step of removing the sacrifice layers 303 and 305 (see FIG. 51) due to the small etching rates of BHF, so that the sonic sensor 300a attains high performance and implements a high yield.

Although the present invention has been described and illustrated in detail, it is clearly understood that the same is by way of illustration and example only and is not to be taken by way of limitation, the spirit and scope of the present invention being limited only by the terms of the appended claims.

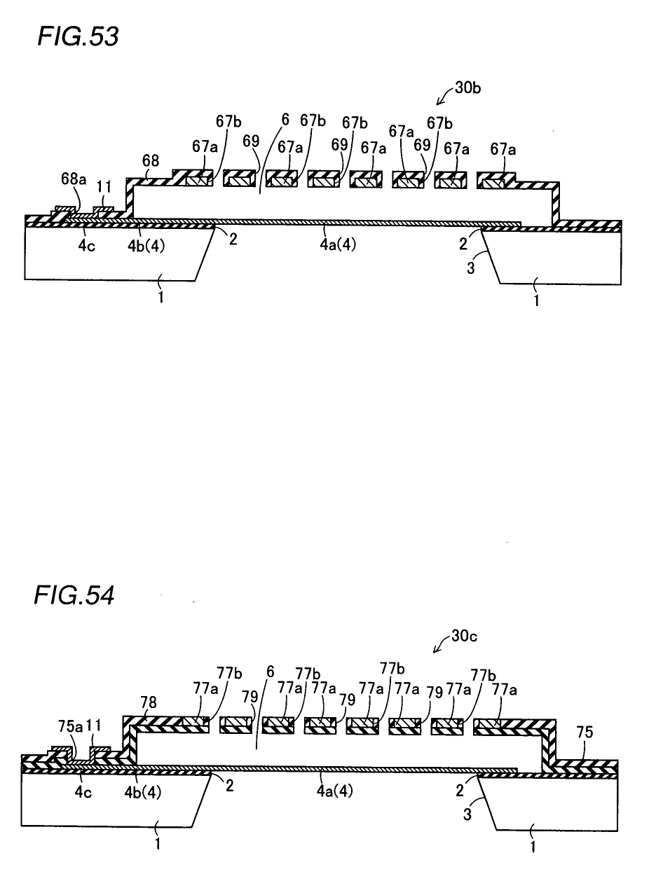

For example, while the lower and upper support layers 5 and 8 of SiN are so formed as to cover both of the lower and upper surfaces of the electrode plate portion 7a in the aforementioned first embodiment and the lower and upper support layers 45 and 48 of SiN are so formed as to cover both of the lower and upper surfaces and the side surface of the electrode plate portion 47a in the aforementioned second embodiment, the present invention is not restricted to this but an upper support layer 68 of SiN may alternatively be so formed as to cover the upper surface of an electrode portion 67a of polysilicon and the overall side surfaces of holes 67b of the electrode plate portion 67a corresponding to sonic holes 69 respectively as in a microphone 30b according to the first modification of the present invention shown in FIG. 53. According to the first modification, as hereinabove described, the upper support layer 68 of SiN having an elastic modulus higher than that of the electrode plate portion 67a of polysilicon is formed on the upper surface and side portions of the lower surface (overall side surfaces of the holes 67b including portions closer to the lower surface) of the electrode plate portion 67a subjected to the maximum tensile stress and the maximum compressive stress upon vibration of the electrode plate portion 67a and the upper support layer 68 so that bearing strength of the upper support layer 68 for the electrode plate portion 67a can be further improved as compared with a case of providing a support layer covering only the upper or lower surface of an electrode plate portion, thereby inhibiting the electrode plate portion 67a from vibration. This point has already been confirmed in the simulation shown in FIG. 14.

Further alternatively, a lower support layer 75 and a side support layer 78 of SiN may be so formed as to cover the lower surface of an electrode plate portion 77a of polysilicon and the side surfaces of holes 77b of the electrode plate portion 77a corresponding to sonic holes 79, as in a microphone 30c according to the second modification of the present invention shown in FIG. 54. According to the second modification, as hereinabove described, the lower support layer 75 and the side support layer 78 of SiN having an elastic modulus higher than that of the electrode plate portion 77a of polysilicon are formed on side portions of the upper surface (overall side surfaces of the holes 77b including portions closer to the upper surface) and the lower surface of the electrode plate portion 77a subjected to the maximum tensile stress and the maximum compressive stress upon vibration of the electrode plate portion 77a, the lower support layer 75 and the side support layer 78 so that bearing strength of the lower support layer 75 and the side support layer 78 for the electrode plate portion 77a can be further improved as compared with a case of providing a support layer covering only the upper or lower surface of an electrode plate portion, thereby inhibiting the electrode plate portion 77a from vibration. This point has already been confirmed in the simulation shown in FIG. 14.

While the aforementioned first and second embodiments and the aforementioned first and second modifications are applied to the microphones 30 and 30a to 30c, the present invention is not restricted to this but may alternatively be applied to another sonic sensor, a pressure sensor or an interdigital electrostatic capacitance detecting sensor such as an acceleration sensor.

While the electrode plate portions 7a, 47a, 67a and 77a are made of polysilicon and the lower support layers 5, 45, 65 and 75 as well as the upper support layers 8, 48, 68 and 78 are made of SiN in the aforementioned first and second embodiments and the aforementioned first and second modifications, the present invention is not restricted to this but the materials for the electrode plate portion 7a, 47a, 67a or 77a and the upper support layer 8, 48, 68 or 78 and the lower support layer 5, 45, 65 or 75 can be properly changed so far as the material constituting the lower support layer 5, 45, 65 or 75 and the upper support layer 8, 48, 68 or 78 has a higher elastic modulus than the material constituting the electrode plate portion 7a, 47a, 67a or 77a. For example, a metallic material such as gold, aluminum or copper may be employed as the material constituting the electrode plate portion 7a, 47a, 67a or 77a, and SiC, SiOC, SiON or SiCN may be employed as the material constituting the lower support layer 5, 45, 65 or 75 and the upper support layer 8, 48, 68 or 78.

While the modified SiOC layers containing the impurities introduced by ion implantation are employed as the supports consisting of the insulating films supporting the fixed electrodes (electrode plates) in the aforementioned third and fourth embodiments, the present invention is not restricted to this but insulating films of a material other than SiOC may alternatively be employed so far as large compressive stress is caused in the films due to an impurity introduced by ion implantation.

While the modified SiOC layers containing ion-implanted boron are employed as the supports of the insulating films supporting the fixed electrodes (electrode plates) in the aforementioned third and fourth embodiments, the present invention is not restricted to this but an impurity other than boron may alternatively be introduced into the insulating films so far as the impurity can cause large compressive stress in the SiOC layers due to ion implantation.

What is claimed is:

1. A sensor comprising:
a diaphragm provided in a vibrative manner;
an electrode plate, opposed to said diaphragm at a prescribed distance, having a hole; and
a support made of a material having an elastic modulus higher than the elastic modulus of a material constituting said electrode plate for supporting said electrode plate, wherein
said support is so formed as to cover at least two of the upper surface and the lower surface of said electrode plate and the side surface of said hole.

2. The sensor according to claim 1, wherein
said support is so formed as to cover the upper surface and the lower surface of said electrode plate.

3. The sensor according to claim 1, wherein
the ratio of the longitudinal sectional area of said support to the total longitudinal sectional area of said electrode plate and said support in portions of said support covering the upper surface and the lower surface of said electrode plate is at least 10%.

4. The sensor according to claim 1, wherein
said support is so formed as to cover either the upper surface or the lower surface of said electrode plate and the side surface of said hole.

5. The sensor according to claim 4, wherein
the ratio of the longitudinal sectional area of said support to the total longitudinal sectional area of said electrode plate and said support in portions of said support covering either the upper surface or the lower surface of said electrode plate and the side surface of said hole is at least 26%.

6. The sensor according to claim 1, wherein
said support is so formed as to cover the upper surface and the lower surface of said electrode plate and the side surface of said support.

7. The sensor according to claim 6, wherein
the ratio of the longitudinal sectional area of said support to the total longitudinal sectional area of said electrode plate and said support in portions of said support covering the upper surface and the lower surface of said electrode plate and the side surface of said support is at least 17%.

8. The sensor according to claim 1, wherein
said electrode plate consists of silicon, and
said support consists of SiN.

9. The sensor according to claim 1, wherein
said support includes an upper support layer covering the upper surface of said electrode plate, and
said upper support layer includes a first opening provided in a contact region of said electrode plate for exposing a prescribed portion of the upper surface of said electrode plate.

10. The sensor according to claim 9, further comprising a first pad electrode so formed as to come into contact with said electrode plate through said first opening of said upper support layer.

11. The sensor according to claim 1, wherein
said support includes an upper support layer covering the upper surface of said electrode plate and a lower support layer covering the lower surface of said electrode plate or the lower surface of said upper support layer, and
said upper support layer and said lower support layer include second openings provided in a contact region of said diaphragm for exposing a prescribed portion of the upper surface of said diaphragm.

12. The sensor according to claim 11, further comprising a second pad electrode so formed as to come into contact with said diaphragm through said second openings of said upper support layer and said lower support layer.

13. The sensor according to claim 1, wherein
said support is formed by an insulating film.

14. The sensor according to claim 13, wherein
said support is formed by said insulating film containing an impurity introduced by ion implantation.

15. The sensor according to claim 14, wherein
said support formed by said insulating film containing said impurity introduced by ion implantation contains Si, O and C.

16. The sensor according to claim 14, wherein
said insulating film includes a first region containing said impurity and a second region containing no said impurity.

17. The sensor according to claim 14, wherein
said impurity is introduced into said electrode plate through said insulating film.

18. The sensor according to claim 14, wherein
said support formed by said insulating film has stress outwardly pulling said electrode plate.

19. The sensor according to claim 1, including a sonic sensor.

20. A sensor comprising:
a first electrode provided on a semiconductor substrate;
a second electrode opposed to said first electrode at a prescribed interval for constituting a capacitor with said first electrode; and
an insulating film provided on at least the upper surface of said second electrode for fixing said second electrode to said semiconductor substrate, wherein
an impurity is introduced into said insulating film by ion implantation.
